(19) United States
(12) Patent Application Publication
(10) Pub. No.: US 2025/0071980 A1
(43) Pub. Date: Feb. 27, 2025

(54) SEMICONDUCTOR DEVICE

(71) Applicant: Samsung Electronics Co., Ltd., Suwon-si (KR)

(72) Inventors: Wonyoung JEONG, Suwon-si (KR); Choonghyun LEE, Suwon-si (KR); Jooncheol KIM, Suwon-si (KR); Sunyoung LEE, Suwon-si (KR); Youngseung CHO, Suwon-si (KR)

(73) Assignee: Samsung Electronics Co., Ltd., Suwon-si (KR)

(21) Appl. No.: 18/755,088

(22) Filed: Jun. 26, 2024

(30) Foreign Application Priority Data
Aug. 23, 2023 (KR) 10-2023-0110444

(51) Int. Cl. H10B 12/00

(52) U.S. Cl. CPC H10B 12/50; H10B 12/09; H10B 12/315; H10B 12/482

(57) ABSTRACT

A semiconductor device may include a substrate including, lower bit line structures from a first region to a second region adjacent to the first region and extending in a second direction perpendicular to the first direction, a second gate structure on the second region of the substrate to be spaced apart from the lower bit line structure, a first offset spacer on a first sidewall corresponding to an end of each of the lower bit line structures in the second direction, a second offset spacer and a first spacer sequentially arranged on a sidewall of the second gate structure, an insulation liner layer at least disposed a surface of the first offset spacer, and a capping pattern covering the lower bit line structures and an upper portion of the second gate structure. The first offset spacer and the insulation liner layer include silicon nitride.

### CROSS-REFERENCE TO RELATED APPLICATION

This application claims priority under 35 USC § 119 to Korean Patent Application No. 10-2023-0110444, filed on Aug. 23, 2023, in the Korean Intellectual Property Office (KIPO), the contents of which are incorporated by reference herein in their entirety.

### BACKGROUND

Various example embodiments relate to a semiconductor device. Particularly, various example embodiments relate to a dynamic random access memory (DRAM) device.

As the DRAM device become highly integrated, a line width of bit line structure included in the DRAM device may be decreased. In a patterning process of the bit line structure, defects such as cutting of the bit line structure or removing portions of the bit line structure may occur.

### SUMMARY

Various example embodiments provide a method of manufacturing a semiconductor device having improved or excellent characteristics.

According to some example embodiments, there is provided a semiconductor device. The semiconductor device may include a substrate including a first region and a second region;
first gate structures extending in a first direction, each of the first gate structures in a first recess defined at the first region of the substrate; lower bit line structures on the substrate, the lower bit line structures arranged from the first region to the second region adjacent to the first region, the lower bit line structures extending in a second direction perpendicular to the first direction; a second gate structure on the second region of the substrate, the second gate structure spaced apart from the lower bit line structure; a first offset spacer on a first sidewall corresponding to an end of each of the lower bit line structures in the second direction; a second offset spacer and a first spacer sequentially arranged on a sidewall of the second gate structure; an insulation liner layer conformally on the upper surfaces of the lower bit line structures, conformally on a surface of the first offset spacer, conformally on the substrate between the lower bit line structure and the second gate structure, and conformally on the upper surfaces of the first spacer and the second gate structure; and a capping pattern covering the lower bit line structures and an upper portion of the second gate structure. The first offset spacer and the insulation liner layer include silicon nitride.

Alternatively or additionally according to some example embodiments, there is provided a semiconductor device. The semiconductor device may include a substrate including first and second regions; a first active pattern and a first device isolation pattern on the first region of the substrate; a second active pattern and a second device isolation pattern on the second region of the substrate; first gate structures in first recesses of the substrate of the first region, each of the first gate structures extending in the first direction; a lower bit line structure on the substrate extending in a second direction perpendicular to the first direction, the lower bit line structure arranged from the first region to the second region adjacent to the first region; a second gate structure on the second region of the substrate, the second gate structure spaced apart from the lower bit line structure; a first offset spacer and a first insulation liner layer on a first sidewall corresponding to an end of each of the lower bit line structures in the second direction; and a second offset spacer, a first spacer, and a second insulation liner layer sequentially arranged on a sidewall of the second gate structure. The first offset spacer and the first insulation liner layer have no silicon oxide.

Alternatively or additionally according to some example embodiments, there is provided a semiconductor device. The semiconductor device may include a substrate including first and second regions; a first active pattern and a first device isolation pattern on the first region of the substrate; a second active pattern and a second device isolation pattern on the second region of the substrate; first gate structures in a first recess of the first region of the substrate, the first gate structures extending in a first direction; lower bit line structures on the substrate, the lower bit line structures arranged from the first region to the second region adjacent to the first region, the lower bit line structures extending in a second direction perpendicular to the first direction, and the lower bit line structures including at least tungsten; a second gate structure on the second region of the substrate to be spaced apart from the lower bit line structures, and the second gate structure including a conductive material the same as a material of the lower bit line structure; a first offset spacer on a first sidewall corresponding to an end of each of the lower bit line structures in the second direction; a second offset spacer and a first spacer sequentially arranged on a sidewall of the second gate structure; and an insulation liner layer conformally on each of upper surfaces of the lower bit line structures, the surface of the first offset spacer, the second device isolation pattern between the lower bit line structure and the second gate structure, and upper surfaces of the first spacer and the second gate structure.

In semiconductor devices according to various example embodiments, a spacer formed on a sidewall of an end of the lower word line structure in an extension direction may not include oxide. Accordingly, defects in which portions of the conductive pattern included in the lower word line structure is cut off between upper portion and lower portion due to the oxide formed on the sidewall of the end of the lower word line structure may be decreased, and/or an impact from defects may be decreased, at an edge portion of the lower word line in the extension direction.

### BRIEF DESCRIPTION OF THE DRAWINGS

Various example embodiments will be more clearly understood from the following detailed description taken in conjunction with the accompanying drawings. FIGS. 1 to 35 represent various non-limiting, example embodiments as described herein.

FIGS. 1 to 31 are cross-sectional views and plan views for illustrating a method of manufacturing a semiconductor device according to some example embodiments; and

FIGS. 32 to 35 are cross-sectional views illustrating a method for manufacturing a semiconductor device according to some example embodiments.

### DETAILED DESCRIPTION

Hereinafter, various example embodiments will be described in detail with reference to the accompanying drawings.

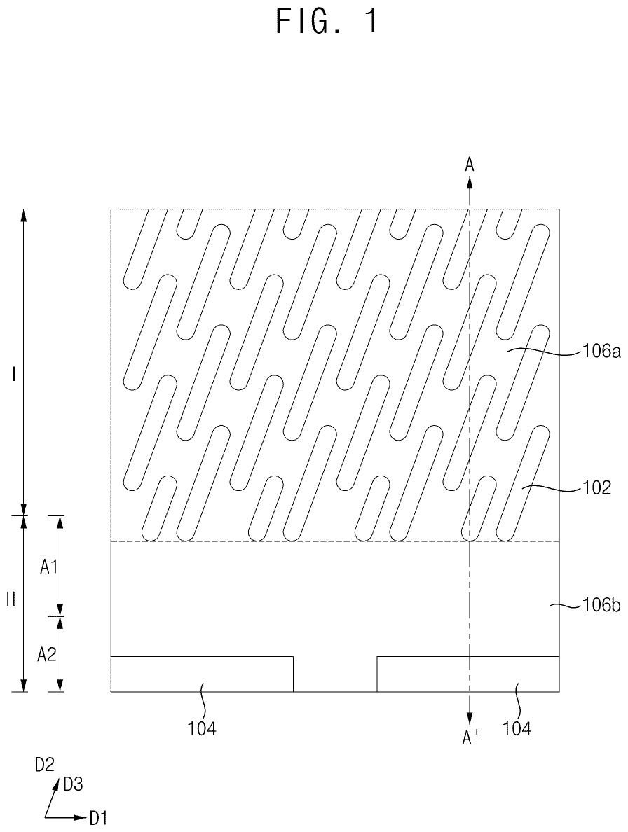

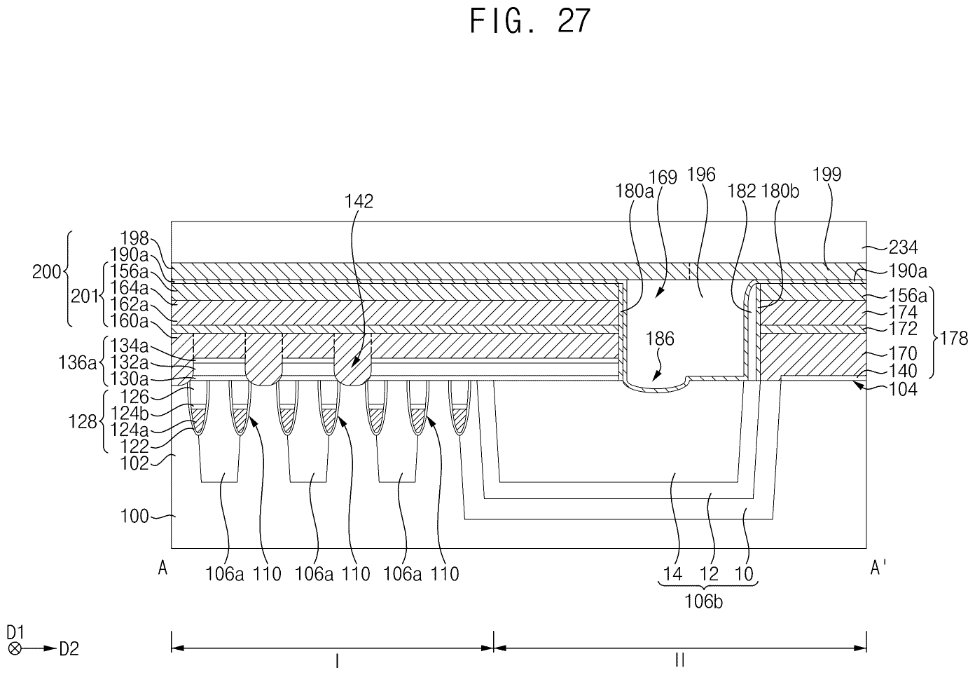

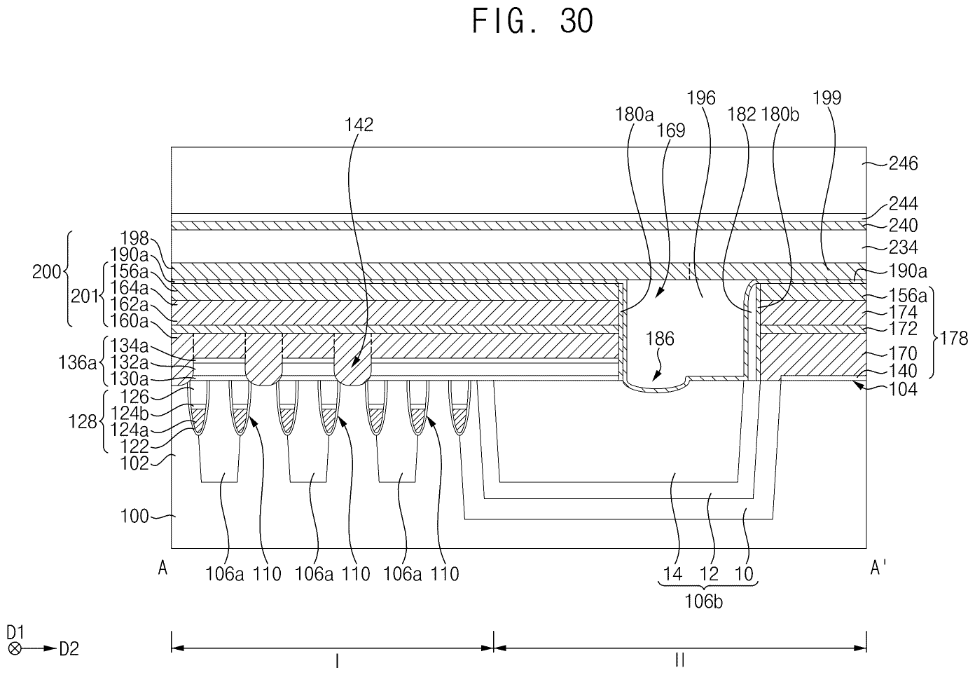

FIGS. 1 to 31 are cross-sectional views and plan views for illustrating a method of manufacturing a semiconductor device according to some example embodiments.

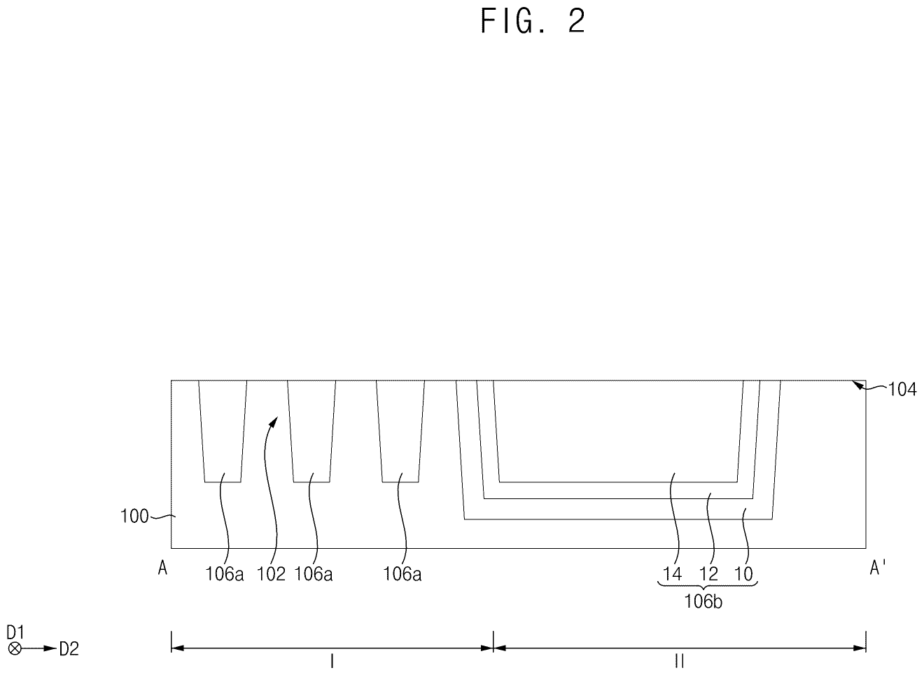

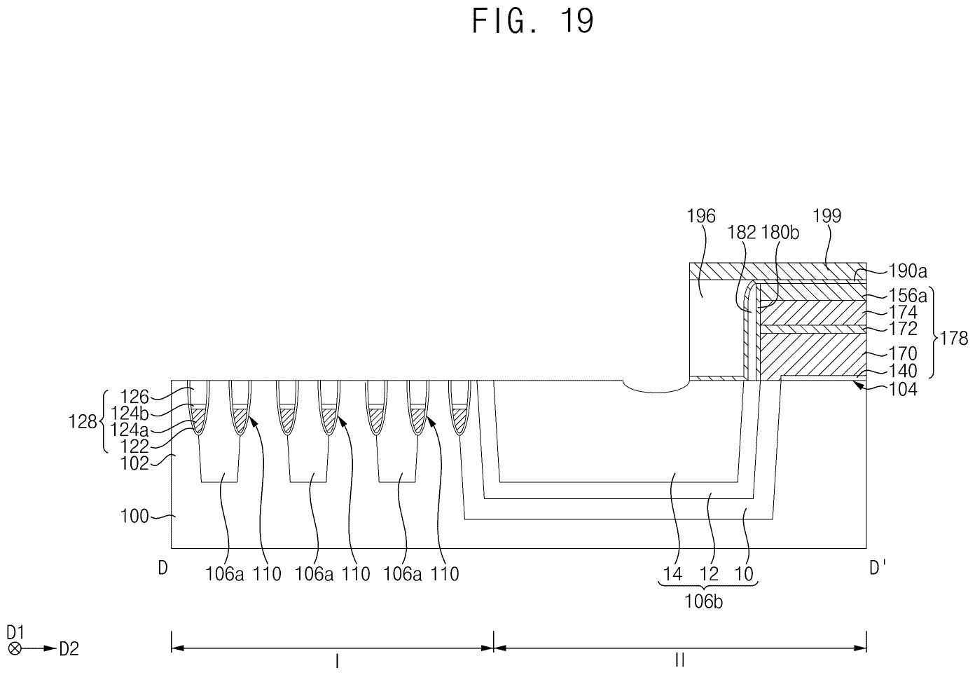

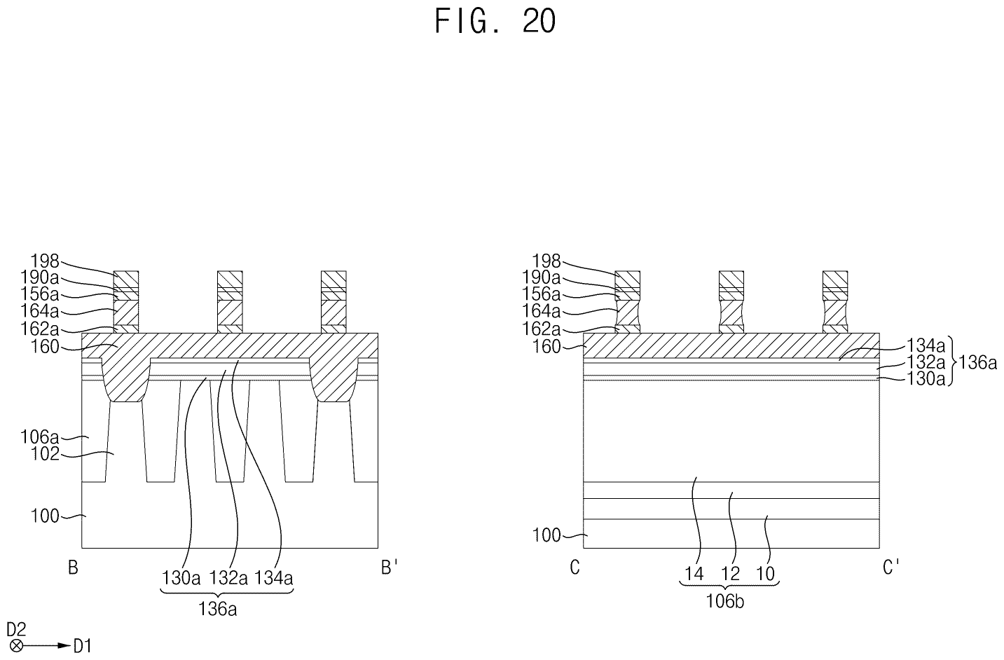

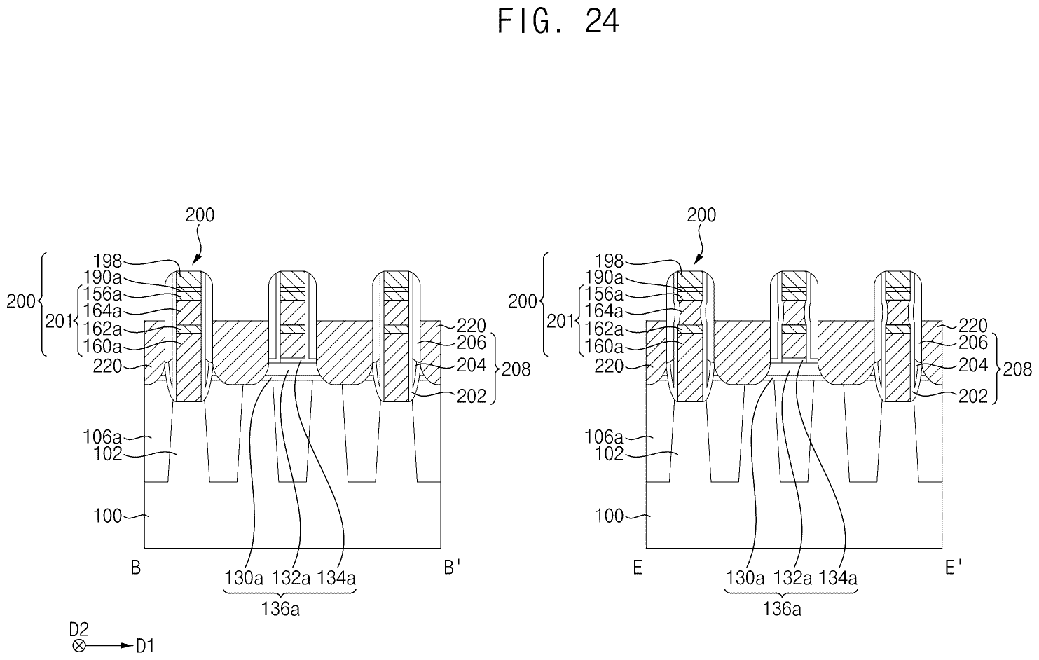

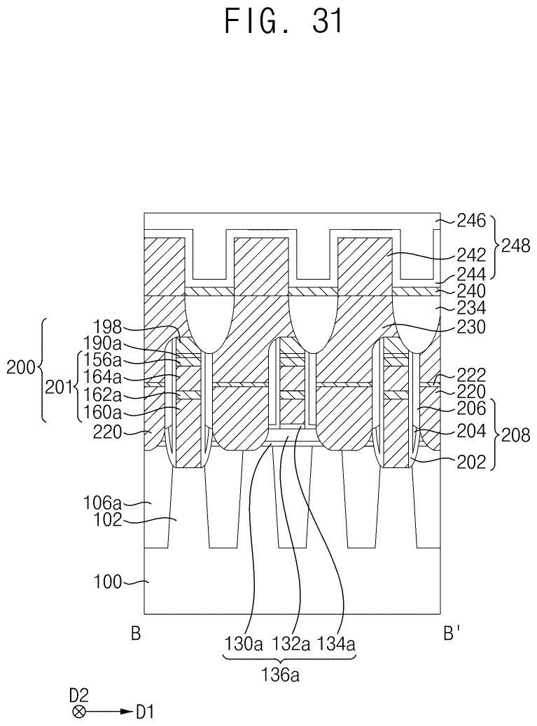

Particularly, FIGS. 1, 4, 6, 9, 11, 14, 17, 23, 26 and 29 are plan views, and FIGS. 2, 3, 5, 7, 8, 10, 12, 13, 15, 16, 18 to 22, 24, 25, 27, 28, 30 and 31 are cross-sectional views. FIGS. 2, 3, 5, 7, 8, 10, 12, 13, 15, 16, 18, 27 and 30 are cross-sectional views taken along line A-A′in the plan view. FIGS. 20, 21 and 22 include cross-sectional views taken along line B-B′ and line C-C′ in the plan view. FIGS. 24, 25, and 28 include cross-sectional views taken along lines B-B′ and E-E′ in the plan view. FIG. 19 includes a cross-sectional view taken along line D-D′ in the plan view. FIG. 31 includes a cross-sectional view taken along line B-B′in the plan view.

In the detailed description below, two directions interesting, e.g., perpendicular to each other among horizontal directions parallel to an upper surface of a substrate are defined as first and second directions D1 and D2, respectively. A direction having an acute angle with respect to each of the first direction and the second direction is defined as a third direction D3. In addition, a direction perpendicular to the upper surface of the substrate is referred to as a vertical direction.

Referring to FIGS. 1 and 2, active patterns 102 and 104 and device isolation patterns 106a and 106b may be formed on or within a substrate 100 that includes a first region I and a second region II. The first region I of the substrate 100 may be or may correspond to a region where memory cells are formed. The second region II of the substrate 100 may be adjacent to the first region I and/or may surround or at least partly surround the first region I. The second region II of the substrate 100 may include a dummy cell region A1 in which dummy memory cells (e.g., electrically inactive cells) are formed, and a core/peripheral region A2 outside the dummy cell region A1. The dummy cell region A1 may be or correspond to an interface region between the core/peripheral region A2 and the first region I.

The active patterns 102 and 104 may be formed by removing an upper portion of the substrate 100 to form a trench. The device isolation patterns 106a and 106b may be formed by filling the trench with an insulation material such as but not limited to silicon oxide, e.g., with a process such as but not limited to a shallow trench isolation (STI) process. Alternatively or additionally the device isolation patterns 106a and 106b may be formed with a spin-on glass (SOG) process; example embodiments are not limited thereto.

Each of first active patterns 102 on the first region I may have an isolated shape (such as an island shape) extending in the third direction D3. A plurality of first active patterns 102 may be spaced apart from each of the first and second directions D1 and D2. A first device isolation pattern 106a may be formed between the first active patterns 102.

A second device isolation pattern 106b may be formed on the dummy cell region A1 in the second region II. A portion of the first active pattern 102 may be disposed in the dummy cell region A1 adjacent to the first region I.

Second active patterns 104 and the second device isolation patterns 106b may be formed on the core/peripheral region A2 in the second region II. The second device isolation pattern 106b may have a width greater than a width of the first device isolation pattern 106a. A depth of the trench formed on the second region II of the substrate 100 may be greater than a depth of the trench formed on the first region I of the substrate 100.

In some example embodiments, stacked structures of insulation patterns included in the device isolation pattern may vary depending on the width of the trenches. For example, the first device isolation pattern 106a may include only a first insulation pattern 10 or may include the first insulation pattern 10 and the second insulation pattern 12, depending on positions of the first device isolation pattern 106a. The second device isolation pattern 106b may include the first insulation pattern 10, the second insulation pattern 12, and a third insulation pattern 14 sequentially stacked in the trench. In some example embodiments, the first insulation pattern 10 and the third insulation pattern 14 may include, e.g., silicon oxide, and may or may not include silicon nitride and the second insulation pattern 12 may include, e.g., silicon nitride, and may or may not include silicon oxide. Most of an upper surface of the second device isolation pattern 106b may expose the silicon oxide.

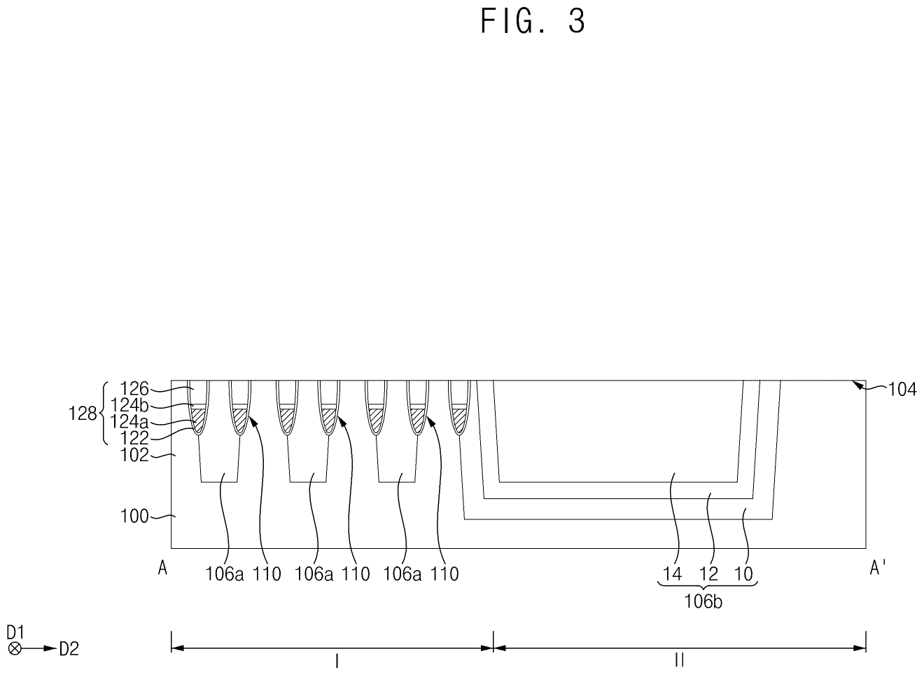

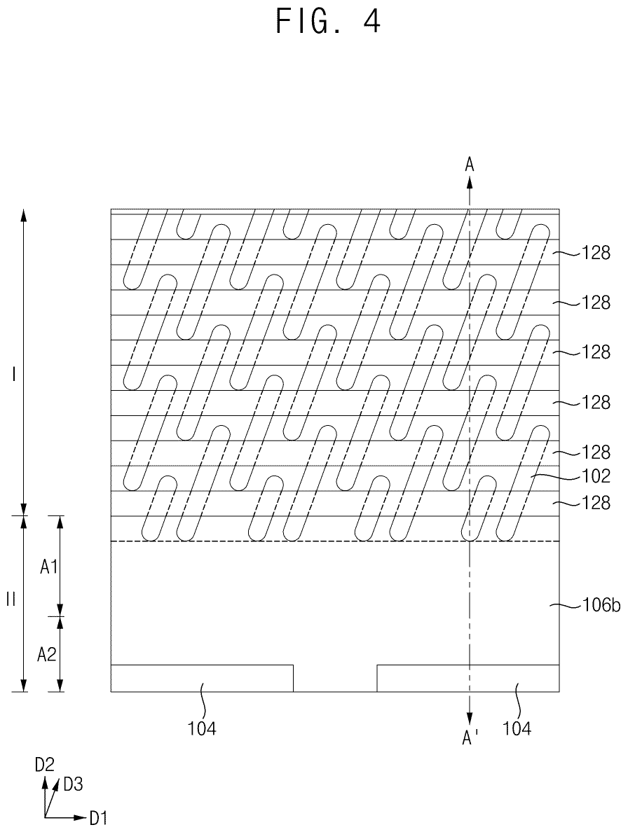

Referring to FIGS. 3 and 4, the first active pattern 102 and the first device isolation pattern 106a on the first region I may be partially etched to form a first recess 110 extending in the first direction D1.

A first gate structure 128 may be formed in the first recess 110. The first gate structure 128 may extend in the first direction D1 on and/or at least partly in the first region I of the substrate 100. A plurality of first gate structures 128 may be formed to be spaced apart from each other in the second direction D2. The first gate structure 128 may include a first gate insulation layer 122, first gate electrodes 124a and 124b, and a first gate mask 126. In some example embodiments, the first gate electrodes 124a and 124b may include a first conductive pattern 124a including tungsten and a second conductive pattern 124b including polysilicon such as doped polysilicon. In some example embodiments, the first gate electrodes 124a and 124b may be formed with one or more of a chemical vapor deposition (CVD) process such as a low pressure CVD (LPCVD) process and/or a plasma enhanced (PECVD) process and/or an atomic layer (ALD) process, and/or a physical vapor deposition (PVD) process; example embodiments are not limited thereto. The first gate insulation layer 122 may include, e.g., silicon oxide, and the first gate mask 126 may include, e.g., silicon nitride.

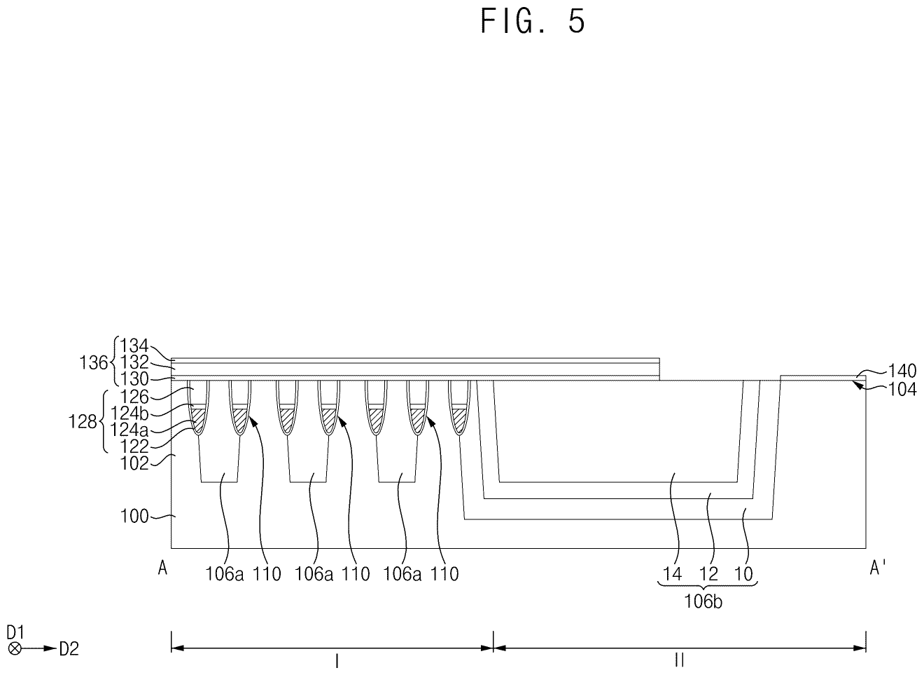

Referring to FIG. 5, a preliminary insulation layer structure 136 may be formed on the first active pattern 102 and the first and second device isolation patterns 106a and 106b in the first region I and the dummy cell region A1. The preliminary insulation layer structure 136 may be a single layer or a multilayer layer. In some example embodiments, the preliminary insulation layer structure 136 may be formed with a deposition process such as one or more of a chemical vapor deposition (CVD) process or a physical vapor deposition (PVD) process or an ALD process, such as but not limited to an in-situ deposition process. The preliminary insulation layer structure 136 may include silicon oxide and/or silicon nitride. In some example embodiments, the preliminary insulation layer structure 136 may include a fourth insulation layer 130 including the silicon oxide, a fifth insulation layer 132 including the silicon nitride, and a sixth insulation layer 134 including the silicon oxide.

Thereafter, the second gate insulation layer 140 may be formed on the second active pattern 104 in the second region II by performing, e.g., a thermal oxidation process. The upper surface of the second device isolation pattern 106b may be exposed between the preliminary insulation layer structure 136 and the second gate insulation layer 140 on the second region II.

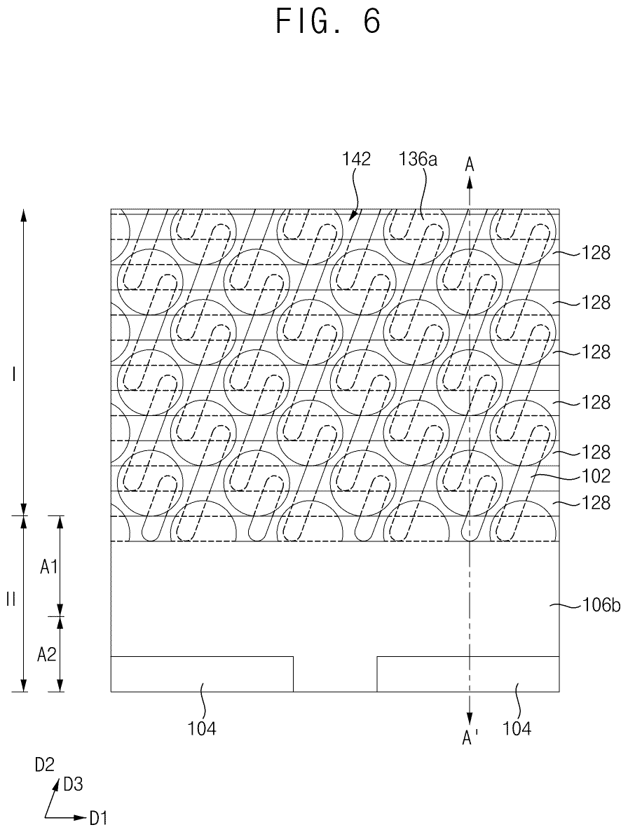

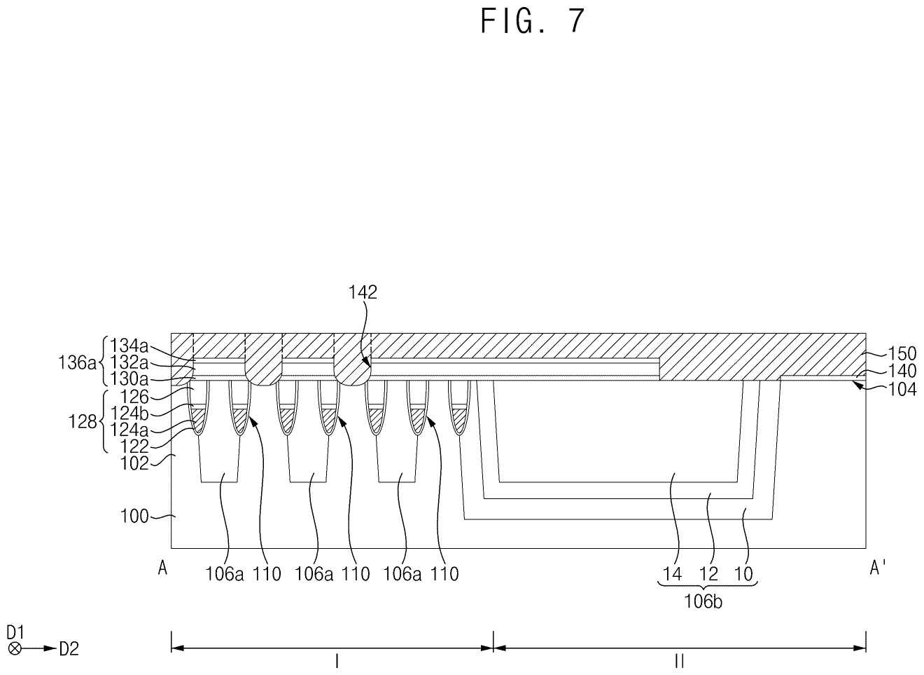

Referring to FIGS. 6 and 7, a third preliminary conductive layer may be formed on the preliminary insulation layer structure 136, the second gate insulation layer 140, and the second device isolation pattern 106b. The preliminary third conductive layer may include, e.g., polysilicon such as doped or undoped polysilicon.

Portions of the preliminary third conductive layer and preliminary insulation layer structure 136 on the first region I may be etched (e.g., with a wet and/or dry etch), and then the first active pattern 102, the first device isolation pattern 106a, and the first gate mask 126 included in the first gate structure 128 thereunder may be partially etched to form a first opening 142. The first opening 142 may expose a central portion of the first active pattern 102 in the third direction D3. As the first opening 142 is formed, an insulation layer structure 136a including an including a fourth insulation pattern 130a, a fifth insulation pattern 132a, and a sixth insulation pattern 134a may be formed.

Thereafter, a conductive pattern may be formed to fill the first opening 142. The conductive pattern may include, e.g., polysilicon such as doped polysilicon. The conductive pattern may contact the central portion of the first active pattern 102 in the third direction D3.

The preliminary third conductive layer and the conductive pattern may be merged into one, so that a third conductive layer 150 including the preliminary third conductive layer and the conductive pattern may be formed. An upper surface of the third conductive layer 150 may be substantially flat; in some example embodiments, the upper surface of the third conductive layer 150 may be planarized, e.g., with a blanket etch process and/or a chemical mechanical planarization (CMP) process.

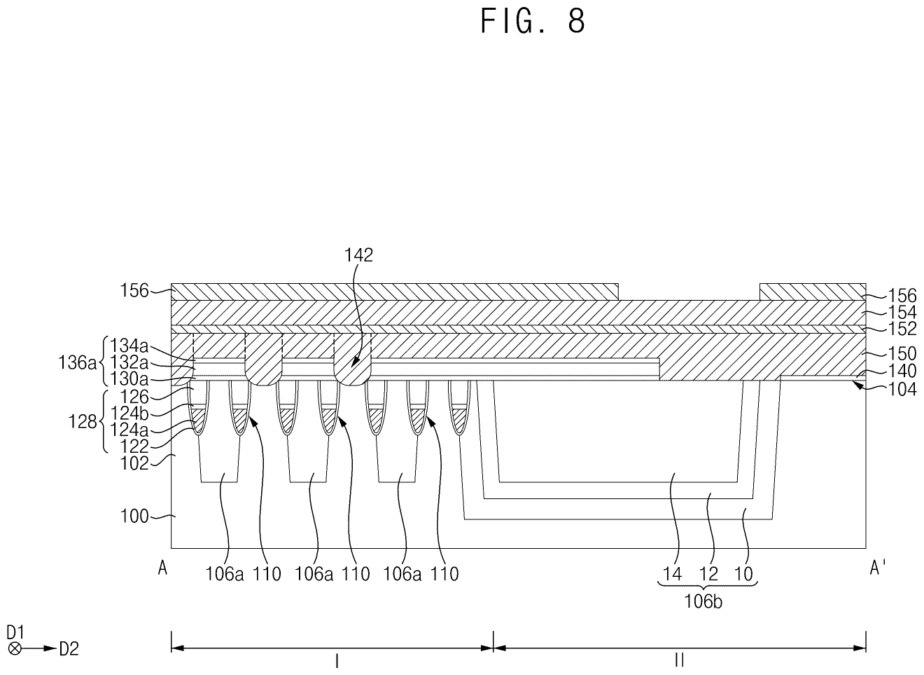

Referring to FIG. 8, a first barrier layer 152 may be formed on the third conductive layer 150, and a fourth conductive layer 154 may be formed on the first barrier layer 152.

For example, the first barrier layer 152 may include, e.g., a metal silicon nitride such as titanium silicon nitride (TiSiN), and the fourth conductive layer 154 may include a metal that can be etched by a dry etching process. The fourth conductive layer 154 may include, e.g., tungsten. The first barrier layer 152 and the fourth conductive layer 154 may be formed with at least one of a CVD process or a PVD process or an ALD process; example embodiments are not limited thereto.

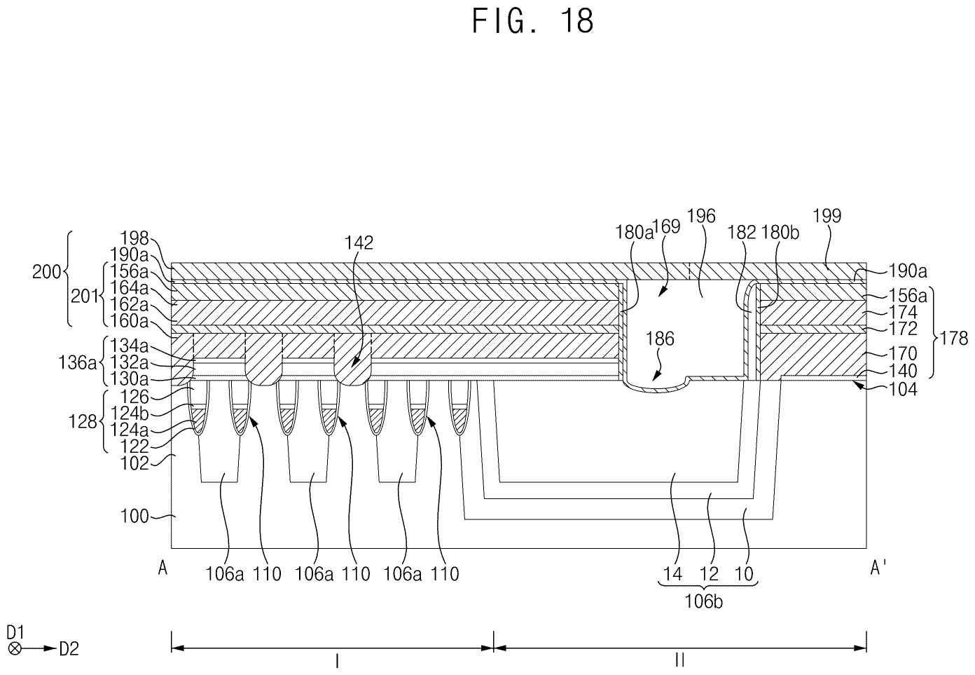

A preliminary first capping pattern 156 may be formed on the fourth conductive layer 154. The preliminary first capping pattern 156 may sufficiently cover the fourth conductive layer 154 on the first region I and the dummy cell region A1. An end in the second direction D2 of a lower bit line structure 201 (referred to as FIG. 18) subsequently formed may be defined by the preliminary first capping pattern 156. In the core/peripheral region A2, the preliminary first capping pattern 156 may cover a region for forming a second gate structure. The preliminary first capping pattern 156 may include, e.g., a nitride such as silicon nitride.

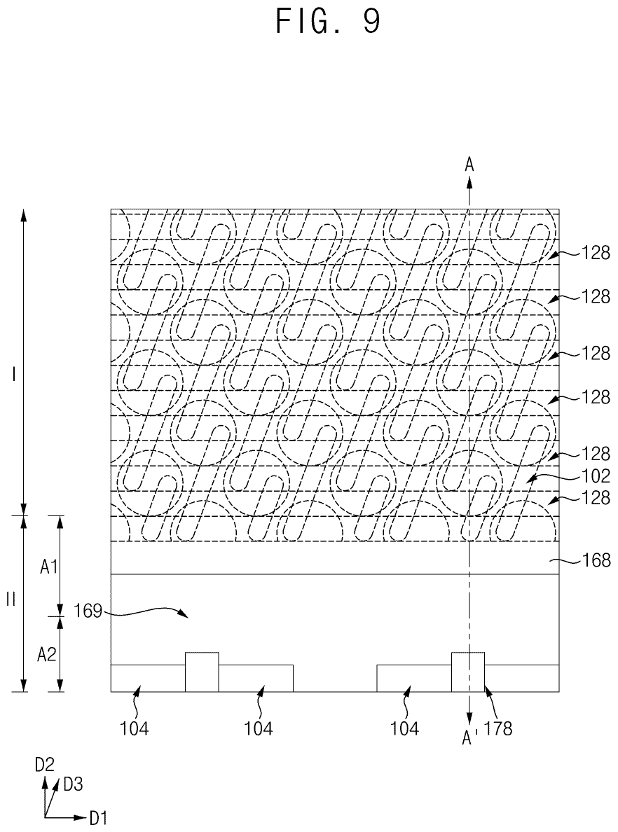

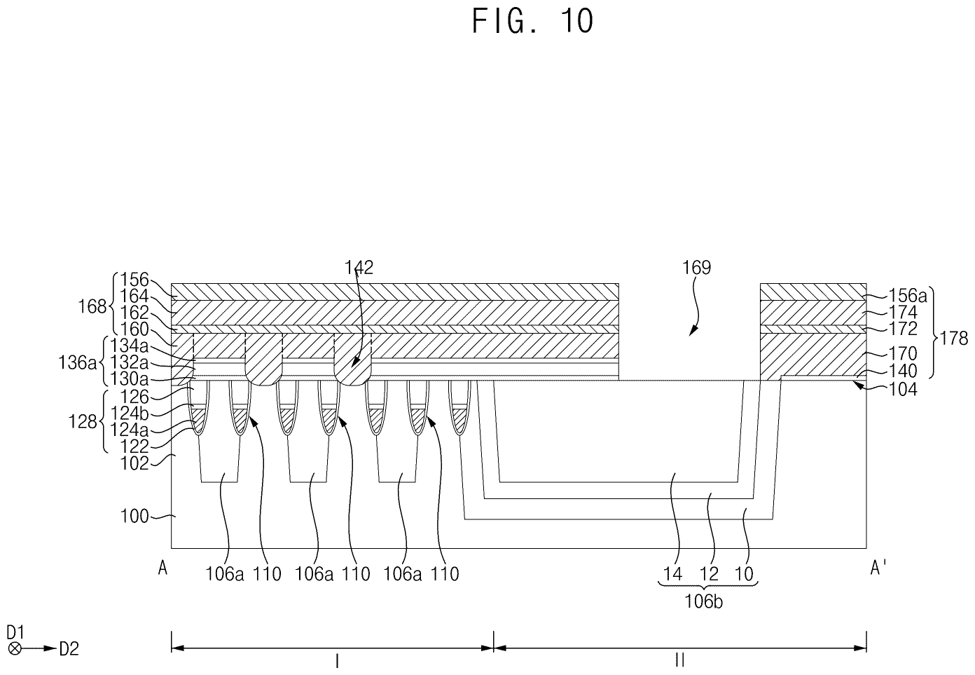

Referring to FIGS. 9 and 10, the fourth conductive layer 154, the first barrier layer 152, the third conductive layer 150, and the insulation layer structure 136a may be etched, e.g., with an anisotropic etch such as a dry etch, using the preliminary first capping pattern 156 as an etch mask to form a preliminary bit line structure 168 and a second gate structure 178. In the etching process, the preliminary first capping pattern 156 may be partially etched, so that a thickness of the preliminary first capping pattern 156 may be decreased.

The preliminary bit line structure 168 may be formed on the insulation layer structure 136a in the first region I and the dummy cell region A1. The preliminary bit line structure 168 may define the end in the second direction D2 of the lower bit line structure 201 subsequently formed. The preliminary bit line structure 168 may cover the first region I and the dummy cell region A1. An end of the preliminary bit line structure 168 in the second direction D2 may be positioned on the second device isolation pattern 106b on the dummy cell region A2.

A second gate structure 178 may be formed on the core/peripheral region A2 of the substrate 100.

In some example embodiments, the preliminary bit line structure 168 may include a preliminary third conductive pattern 160, a preliminary first barrier pattern 162, a preliminary fourth conductive pattern 164, and a preliminary first capping pattern 156 stacked. The second gate structure 178 may include a second gate insulation layer 140, a fifth conductive pattern 170, a second barrier pattern 172, a sixth conductive pattern 174, and a first capping pattern 156a stacked. The fifth conductive pattern 170, second barrier pattern 172, and sixth conductive pattern 174 sequentially stacked may serve as a second gate electrode.

A second opening 169 may be formed between the preliminary bit line structure 168 and the second gate structure 178. The second device isolation pattern 106b may be exposed by a bottom of the second opening 169.

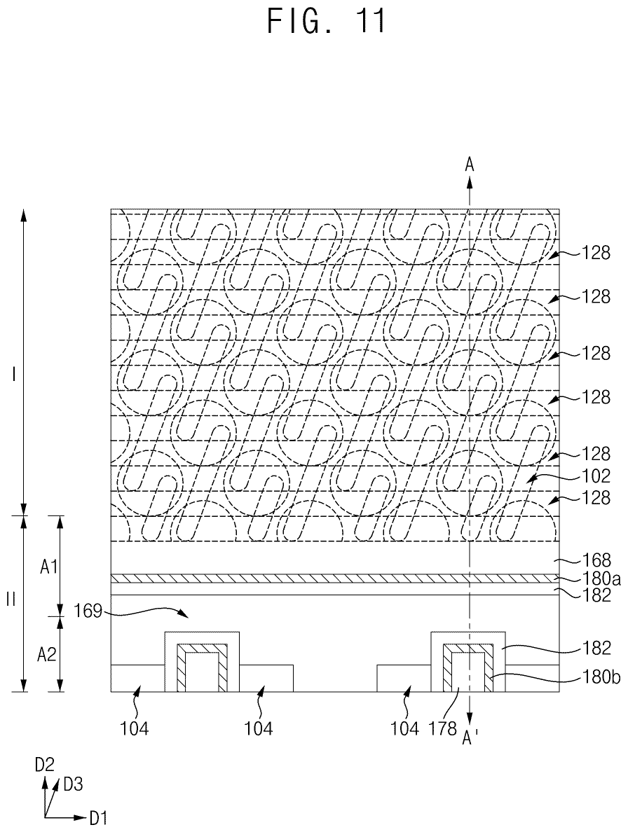

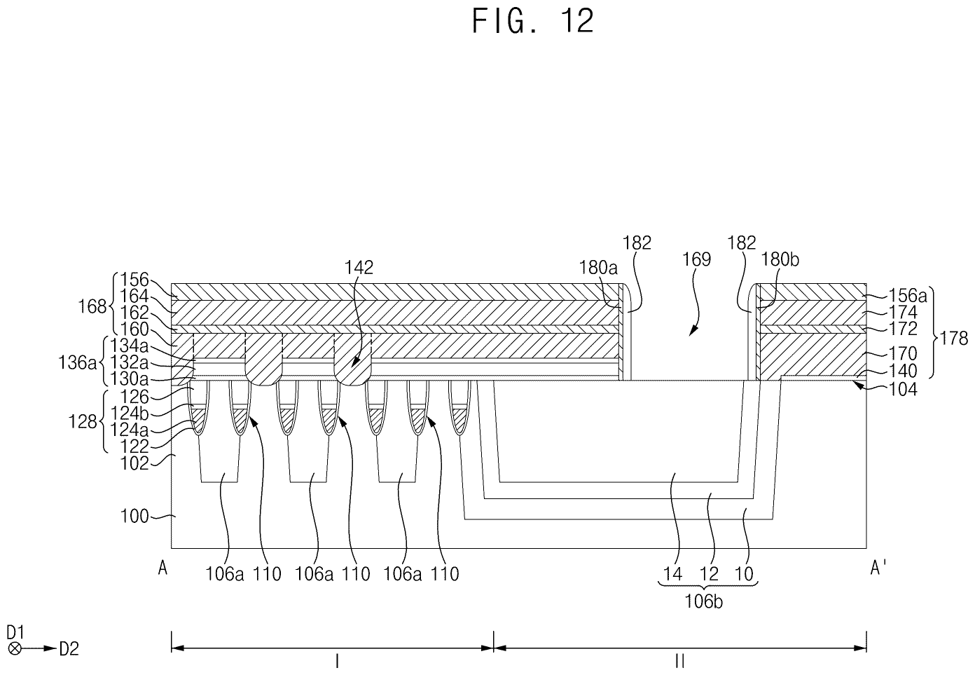

Referring to FIGS. 11 and 12, a first offset spacer 180a may be formed on a sidewall (e.g., the sidewall corresponding to the end in the second direction) of the preliminary bit line structure 168. A second offset spacer 180b may be formed on the sidewall of the second gate structure 178. In some example embodiments the first and second offset spacers 180a and 180b may be formed together by the same processes, and thus the first and second offset spacers 180a and 180b may include the same material. The first and second offset spacers 180a and 180b may include, e.g., silicon nitride. In some example embodiments, the first and second offset spacers 180a and 180b may be formed with a CVD process covering sidewalls of the preliminary bit line structure 168, an upper surface of the preliminary first capping pattern 156, and an upper surface of the exposed portion of the second device isolation pattern 106b, followed by a subsequent etch such as a subsequent blanket etch; example embodiments are not limited thereto.

Thereafter, a first spacer 182 including silicon oxide may be formed on sidewalls of the first and second offset spacers 180a and 180b. The first spacer 182 may have a thickness in a lateral direction greater than a thickness of each of the first and second offset spacers 180a and 180b in the lateral direction. In some example embodiments, the first spacer 182 may be formed with a CVD process covering sidewalls of the first and second offset spacers 180a and 180b, an upper surface of the preliminary first capping pattern 156, and an upper surface of the exposed portion of the second device isolation pattern 106b, followed by a subsequent etch such as a subsequent blanket etch; example embodiments are not limited thereto.

Accordingly, the first offset spacer 180a and the first spacer 182 may be stacked on the sidewall of the preliminary bit line structure 168. The second offset spacer 180b and the first spacer 182 may be stacked on the sidewall of the second gate structure 178.

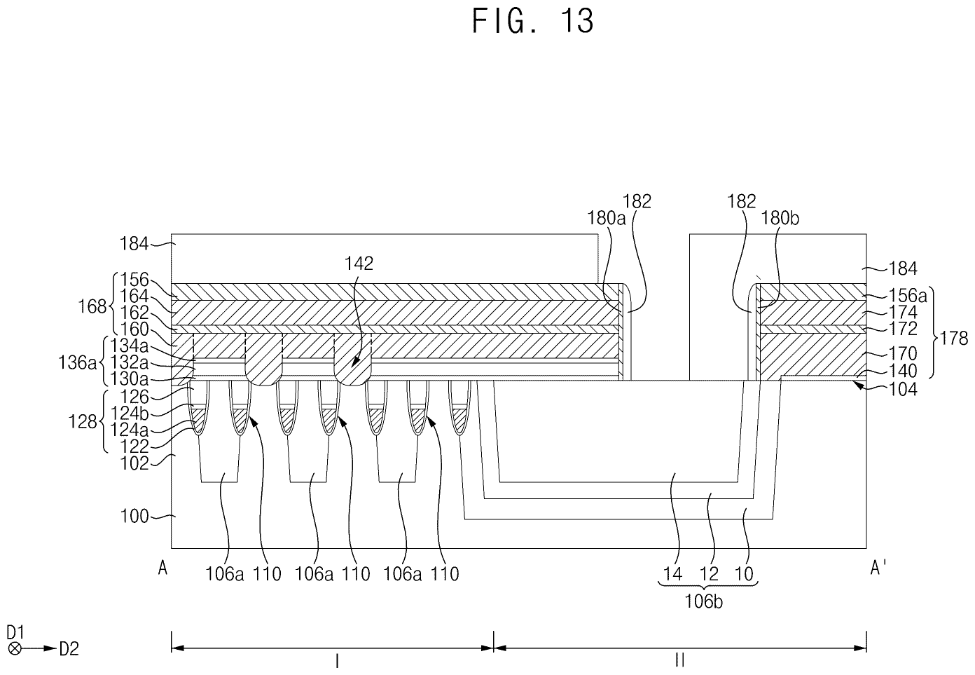

Referring to FIG. 13, a first photoresist pattern 184 may be formed on the preliminary bit line structure 168, the second device isolation pattern 106b, and the second gate structure 178. The first photoresist pattern 184 may expose the first offset spacer 180a and the first spacer 182 on the sidewall of the preliminary bit line structure 168.

In addition, upper surfaces of the preliminary bit line structure 168 and the second device isolation pattern 106b adjacent to the first spacer 182 may be exposed together by the first photoresist pattern 184. The first photoresist pattern 184 may cover at least the upper surface of the preliminary bit line structure 168 on the first region I, and the second gate structure 178, the second offset spacer 180b, the first spacer 182, the second active pattern 104 and a portion of the second device isolation pattern 106b on the core/peripheral region A2.

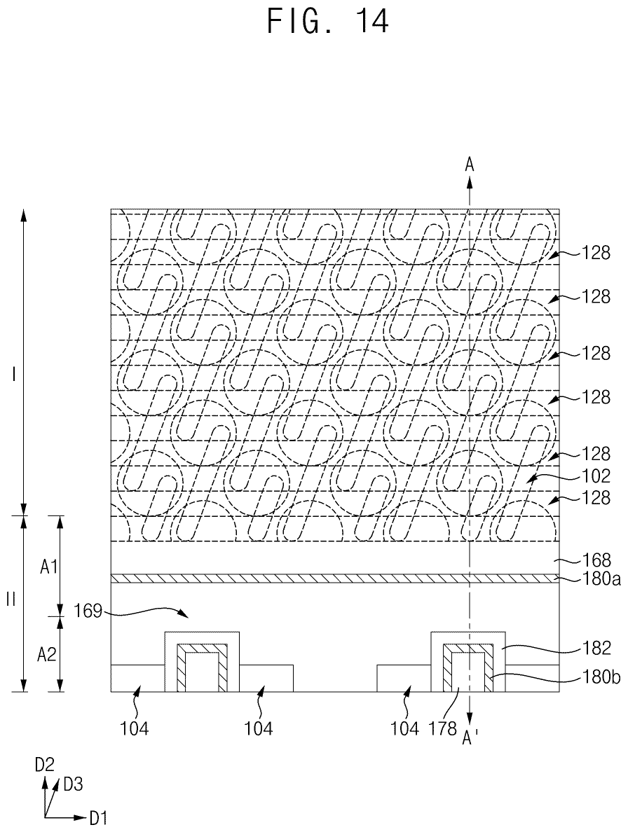

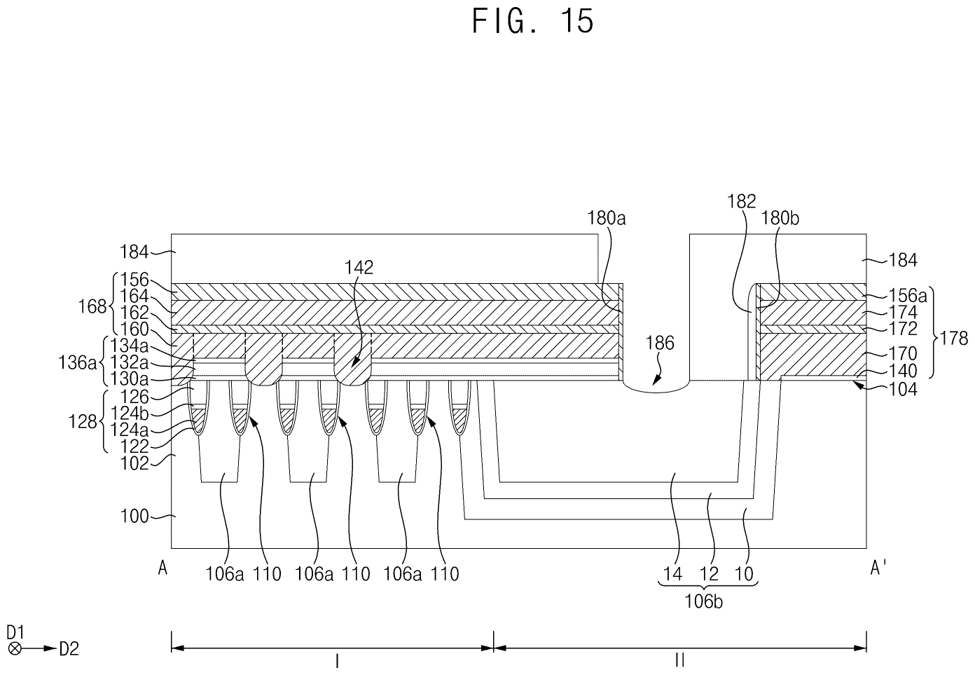

Referring to FIGS. 14 and 15, the first spacer 182 exposed by the first photoresist pattern 184 may be selectively etched by an etching process.

The etching process of the first spacer 182 may include, e.g., a wet etching process. In some example embodiments, the wet etching process may include a buffered hydrogen fluoride (BHF) process; however, example embodiments are not limited thereto. In the etching process, the silicon oxide may be selectively removed. In some example embodiments, etchants used in the wet etching process may include, e.g., a hydrofluoric acid solution including ammonium fluoride.

In the etching process of the first spacer 182, silicon nitride may be hardly or lightly or barely etched. Therefore, the first offset spacer 180a and the preliminary first capping pattern 156 included in the preliminary bit line structure 168 including the silicon nitride may be hardly or barely etched by the etching process of the first spacer 182. When the etching process of the first spacer 182 is performed, the first offset spacer 180a may be exposed on the sidewall of the preliminary bit line structure 168.

In the etching process of the first spacer 182, the second device isolation pattern 106b on the bottom of the second opening 169 exposed by the first photoresist pattern 184 may be etched together or concurrently. Accordingly, a second recess 186 may be formed at a portion of the upper surface of the second device isolation pattern 106b. The second recess 186 may be formed in an area from a region adjacent of the first offset spacer 180a to a region spaced apart from the preliminary bit line structure 168. The second recess 186 may be disposed at an outside of the first offset spacer 180a.

After performing the etching process of the first spacer 182, the second offset spacer 180b and the first spacer 182 on the sidewall of the second gate structure 178 may remain.

Thereafter, the first photoresist pattern 184 may be removed. In some example embodiments, the first photoresist pattern 184 may be removed with an ashing process.

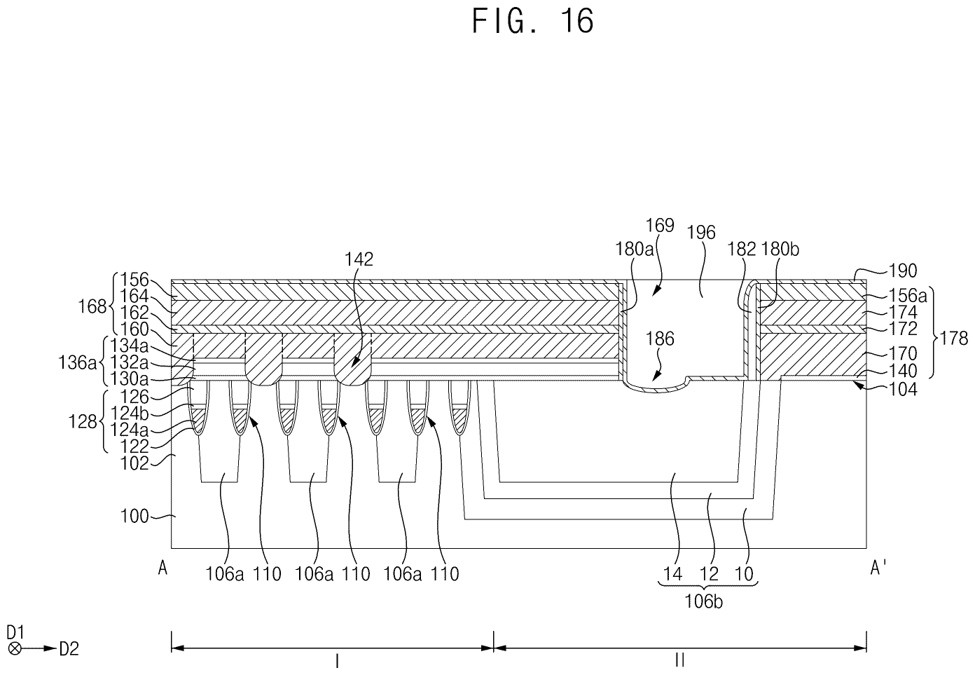

Referring to FIG. 16, an insulation liner layer 190 such as a thin insulation liner layer 190 may be conformally formed on surfaces of each of the preliminary bit line structure 168, the first offset spacer 180a, the second recess 186, the second opening 169, the first spacer 182, and the second gate structure 178. The insulation liner layer 190 may include, e.g., nitride such as a silicon nitride, and in some example embodiments may not include silicon oxide. The insulation liner layer 190 may serve as an etch stop layer in subsequent processes.

In this way, the first offset spacer 180a and the insulation liner layer 190 may be sequentially stacked on the sidewall of the preliminary bit line structure 168. The first spacer 182 including silicon oxide may not be formed on the sidewall of the preliminary bit line structure 168. As such, the first offset spacer 180a and the insulation liner layer 190 on the sidewall of the preliminary bit line structure 168 may include the same material, e.g., silicon nitride, and thus the first offset spacer 180a and the insulation liner layer 190 may be treated as one nitride layer, e.g., a homogenous nitride layer without any observable interface therebetween. The insulation liner layer 190 may be formed on the second device isolation pattern 106b. Therefore, a thickness of the nitride layer formed on the sidewall of the preliminary bit line structure 168 may be greater than the thickness of the nitride layer (e.g., insulation liner layer) formed on the second device isolation pattern 106b.

The second offset spacer 180b, the first spacer 182, and the insulation liner layer 190 may be stacked on the sidewall of the second gate structure 178. As the first spacer 182 including the silicon oxide may be formed on the sidewall of the second gate structure 178, parasitic capacitance between the second gate structures 178 may be decreased, and an insulation characteristic between the second gate structures 178 may be improved.

A seventh insulation layer may be formed on the insulation liner layer 190 to completely fill the second recess 186 and the second opening 169. The seventh insulation layer may include, e.g., the silicon oxide and in some example embodiments may not include silicon nitride.

An upper portion of the seventh insulation layer may be planarized until upper surfaces of the insulation liner layer 190 on the preliminary bit line structure 168 and the second gate structure 178 are exposed to form a seventh insulation pattern 196 filling the second recess 186 and the second opening 169. The planarization process may include an etch-back process and/or a chemical mechanical polishing (CMP) process.

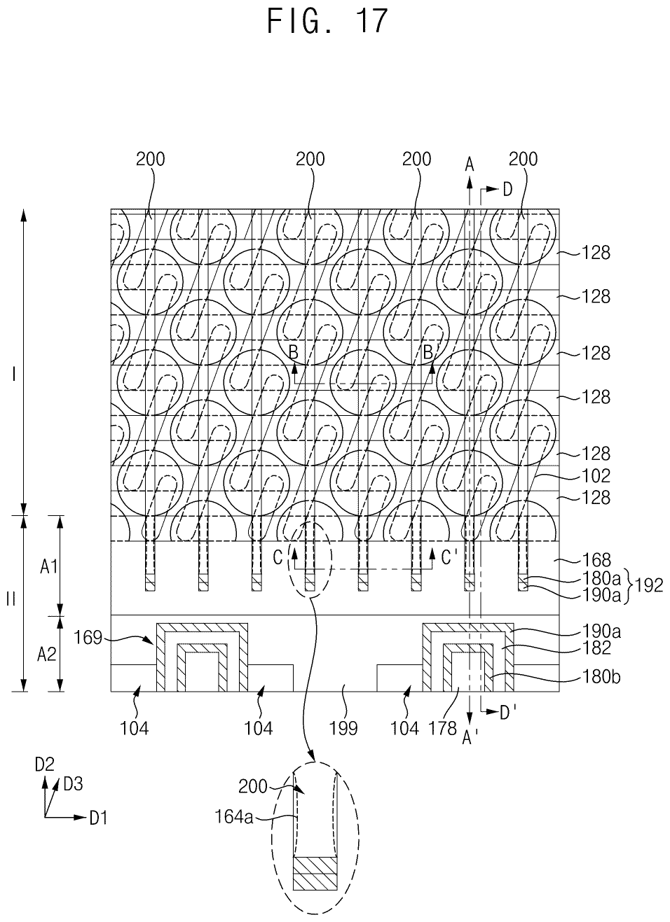

Referring now to FIGS. 17 to 21, a second capping layer 199 may be formed on the seventh insulation pattern 196 and the insulation liner layer 190. The second capping layer 199 may include, e.g., silicon nitride and in some example embodiments may not include silicon oxide.

As shown in FIGS. 19 and 20, the second capping layer 199 on the first region I and the dummy cell region A1 may be patterned to form a second capping pattern 198.

In some example embodiments, the second capping pattern 198 on the first region I and the dummy cell region A1 may extend in the second direction D2. A plurality of second capping patterns 198 on the first region I and the dummy cell region A1 may be spaced from each other in the first direction D1. The second capping layer 199 may remain on the core/peripheral region A2.

The insulation liner layer 190 and the preliminary first capping pattern 156 may be etched, and then the preliminary fourth conductive pattern 164 and the preliminary first barrier layer thereunder may be etched using the second capping pattern 198 as an etch mask.

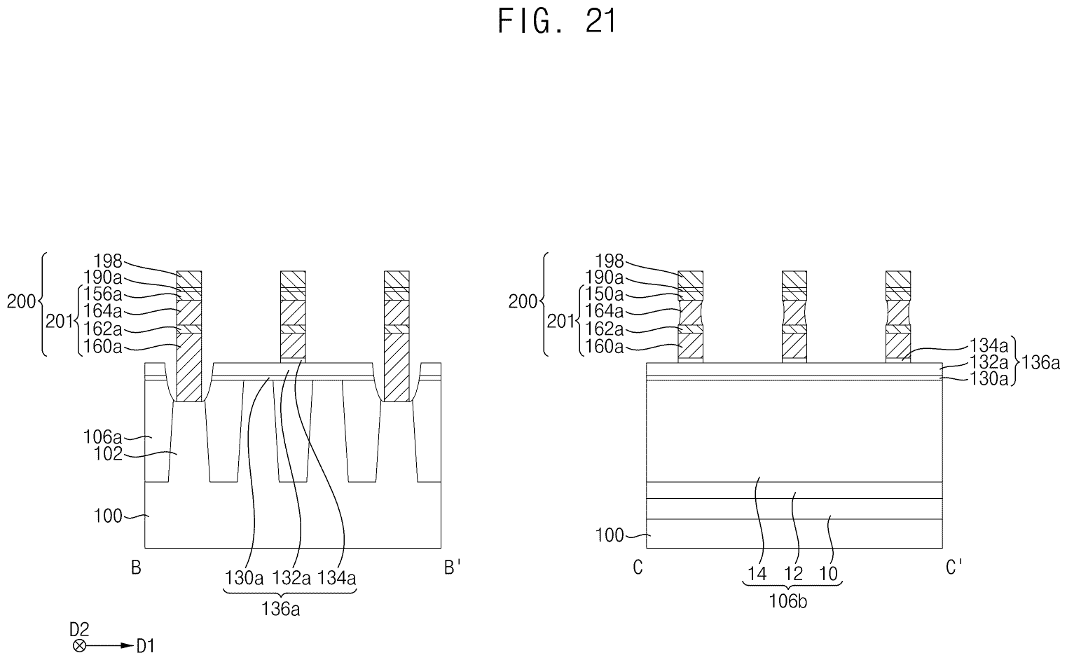

FIG. 20 illustrates that the preliminary first barrier pattern 162 may be etched. FIG. 21 illustrates that a bit line structure 200 may be formed by etching the preliminary third conductive pattern 160.

As shown in FIGS. 20 and 21, the preliminary third conductive pattern 160 may be etched. Additionally, the sixth insulation pattern 134a included in the insulation layer structure 136a may also be etched.

When the etching process is performed, a third conductive pattern 160a, a first barrier pattern 162a, a fourth conductive pattern 164a, the first capping pattern 156a, an insulation liner 190a, and a second capping pattern 198 sequentially stacked may be formed in the first opening 142, and the third conductive pattern 160a may contact the first active pattern 102 in the first opening 142 on the first region I. The third conductive pattern 160a the first barrier pattern 162a, the fourth conductive pattern 164a, the first capping pattern 156a, the insulation liner 190a, and the second capping pattern 198 sequentially stacked may be formed on the sixth insulation pattern 134a outside of the first opening 142.

Hereinafter, the third conductive pattern 160a, the first barrier pattern 162a, the fourth conductive pattern 164a, and the first capping pattern 156a sequentially stacked are referred to as a lower bit line structure 201, and in some example embodiments may correspond to column lines. In addition, the third conductive pattern 160a, the first barrier pattern 162a, the fourth conductive pattern 164a, the first capping pattern 156a, the insulation liner 190a, and the second capping pattern 198 are together referred to as the bit line structure 200.

The bit line structure 200 may extend in the second direction D2 on the first region I. A plurality of bit line structures 200 may be spaced apart from each other in the first direction D1. The bit line structure 200 may extend from the first region I of the substrate 100 to the second region II adjacent to the first region I. For example, the bit line structure 200 may extend from the first region I to the dummy cell region A1.

As shown in FIG. 18, an end of the lower bit line structure 201 in the second direction D2 may be positioned on the dummy cell region A1. The first offset spacer 180a and the insulation liner 190a may cover a sidewall (hereinafter, a first sidewall) of an end of the lower bit line structure 201 in the second direction D2. The first offset spacer 180a and the insulation liner 190a may include, e.g., the silicon nitride, and may be merged into one insulation spacer structure 192. During the etching process, the first offset spacer 180a and the insulation liner layer 190 between the bit line structures 200 may be removed.

The insulation liner 190a and the second capping layer 199 may remain on the second gate structure 178 in the second region II.

Referring to FIG. 20, the etching process for forming the bit line structure 200 may include an etching of the preliminary fourth conductive pattern 164 including tungsten. In the etching process of the preliminary fourth conductive pattern 164, an etching source may include an oxygen (e.g., an O2) source. As the oxygen source increases, an etch rate of tungsten (e.g., the etch rate of the preliminary fourth conductive pattern) may increase. Therefore, in the etching process of the preliminary fourth conductive pattern 164, when a layer including oxygen (such as a silicon oxide layer) is disposed adjacent to the preliminary fourth conductive pattern 164 or is exposed adjacent to the preliminary fourth conductive pattern 164, the etch rate of the tungsten may be increased by diffused oxygen from the layer including the oxygen. Therefore, a portion of the preliminary fourth conductive pattern 164 where the silicon oxide is disposed adjacent to the preliminary fourth conductive pattern 164 may have a higher etch rate than (e.g., a faster etch rate than) a portion of preliminary fourth conductive pattern 164 where an oxygen-including material is not disposed adjacent to the preliminary fourth conductive pattern 164. Therefore, the portion of the preliminary fourth conductive pattern 164 where the silicon oxide is disposed adjacent to the preliminary fourth conductive pattern 164 may be excessively etched.

If the first spacer including the silicon oxide is remained on the first sidewall of the preliminary fourth conductive pattern 164, the preliminary fourth conductive pattern 164 may be excessively etched due to an influence of the silicon oxide of the first spacer adjacent to the preliminary fourth conductive pattern 164. The preliminary fourth conductive pattern 164 corresponding to the end of the lower bit line structure 201 in the second direction D2 may be excessively etched in the lateral direction. When the bit line structure 200 is formed by the etching process, the first sidewall of the fourth conductive pattern positioned at an edge of the lower bit line structure 201 in the second direction D2 may be excessively etched. Therefore, defects such as upper and lower portions between the bit line structure 200 being cut off or decreasing of a line width of the bit line structure 200 may occur.

However, according to some example embodiments, the first spacer including the silicon oxide may not be formed on the first sidewall of the lower bit line structure 201. Therefore, in the etching process for forming the fourth conductive pattern 164a, an oxygen source diffused from the first spacer including the silicon oxide may not be generated or may be less likely to be generated, so that the preliminary fourth conductive pattern 164 may not be excessively etched due to the oxygen source.

Accordingly, when the bit line structure 200 is formed, a line width of the fourth conductive pattern 164a positioned at the edge of the lower bit line structure 201 in the second direction D2 may not be decreased, or may hardly decreased. The fourth conductive pattern 164a positioned at the edge of the lower bit line structure 201 in the second direction D2 may be equal to a first line width of the second capping pattern 198, or slightly less than the first line width. Accordingly, defects in which the fourth conductive pattern 164a positioned at the edge of the lower bit line structure 201 in the second direction D2 cut between an upper portion and a lower portion thereof may be decreased. In some example embodiments, defects in which the fourth conductive pattern 164a included in the lower bit line structure 201 formed on the dummy cell region A1 may be cut between the upper portion and the lower portion thereof may be decreased.

In various example embodiments, referring to a left cross-sectional view of FIGS. 20 and 21, a silicon oxide layer is not disposed adjacent to the preliminary fourth conductive pattern 164 on the first region 1, so that the preliminary fourth conductive pattern 164 may not be excessively etched by the etching process. Accordingly, the fourth conductive pattern 164a on the first region I may have a line width substantially the same as a width of the second capping pattern 198 formed thereon.

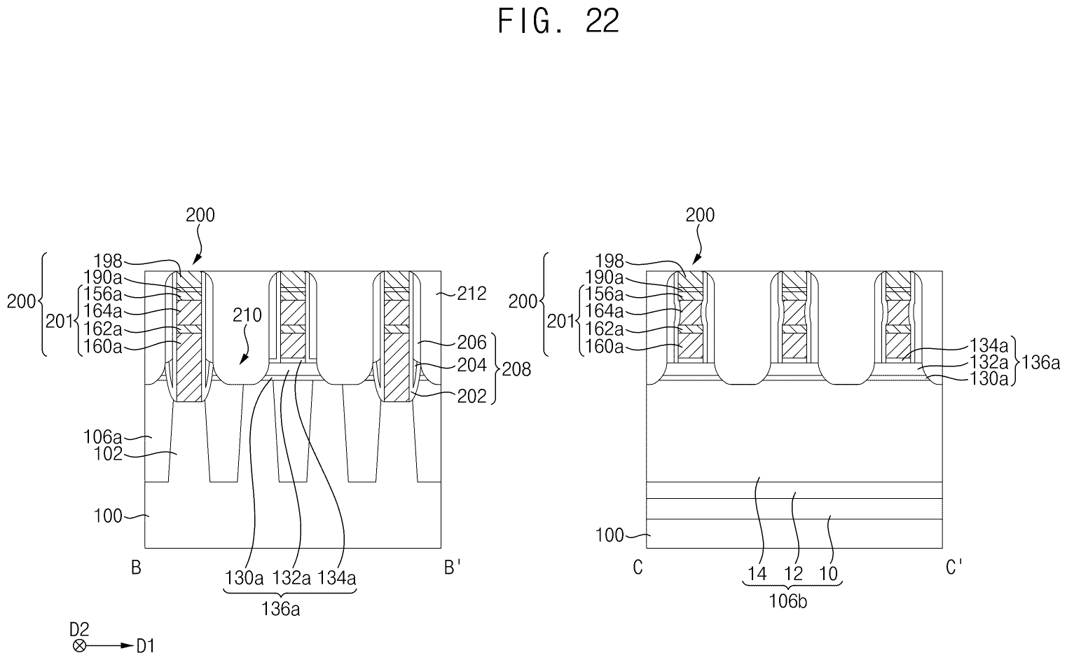

Referring to FIG. 22, a second spacer layer may be formed on surfaces of the bit line structure 200, the first opening 142, the insulation layer structure 136a, and the second capping layer 199. A lower spacer 204 may be formed on the second spacer layer to fill the first opening 142. Most of the surface of the second spacer layer, which is an entire surface of the second spacer layer except for the second spacer layer formed in the first opening 142, may be exposed.

After forming a third spacer layer on exposed surfaces of the second spacer layer and the lower spacer 204, the third spacer layer may be anisotropically etched to form a third spacer covering a sidewall (hereinafter referred to as a second sidewall) facing the bit line structure 200 in the first direction D1. In some example embodiments, the third spacer 206 may include one insulation material or two or more insulation materials stacked.

Thereafter, an etching process, e.g., a dry etching process such as but not limited to a reactive ion etching (RIE) process, may be additionally performed to form a third opening 210 exposing an upper surface of the first active pattern 102. Upper surfaces of the first device isolation pattern 106a and the first capping pattern 156a may also be exposed together by the third opening 210.

By the dry etching process, the first spacer layer formed on upper surfaces of the second capping pattern 198 and the insulation layer structure 136a may be removed to form a first spacer 202 covering the second sidewall of the bit line structure 200. In the dry etching process, a portion of the insulation layer structure 136a may also be removed.

Accordingly, the second spacer 202, the lower spacer 204, and the third spacer 206 may be formed to cover the second sidewall of the bit line structure 200. The second spacer 202, lower spacer 204, and third spacer 206 may be referred to as a spacer structure 208.

A first sacrificial pattern 212 may be formed to fill the gap between the bit line structures 200. In the first region I, the first sacrificial pattern 212 may extend in the second direction D2, and a plurality of the first sacrificial patterns 212 may be spaced apart from each other in the first direction D1 by the bit line structures 200. The first sacrificial patterns 212 may be disposed between the bit line structures 200. The first sacrificial pattern 212 may include an oxide such as silicon oxide and in some example embodiments may not include silicon nitride.

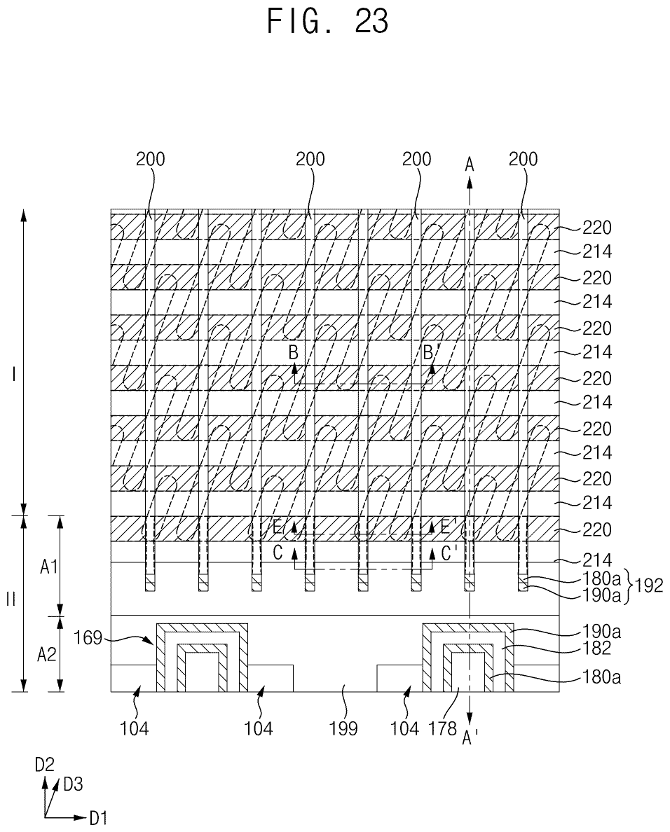

Referring to FIGS. 23 and 24, a portion of the first sacrificial pattern 212 may be etched to form an opening exposing an upper surface of the first gate mask 126 of the first gate structure 128. A plurality of openings may be spaced apart from each other in the second direction D2 between bit line structures 200 adjacent to each other in the first direction D1.

A fence insulation pattern 214 may be formed in the opening. The fence insulation pattern 214 may include, e.g., silicon nitride and may not include silicon oxide. The fence insulation pattern 214 may be disposed between adjacent bit line structures 200, and a plurality of fence insulation patterns 214 may be spaced apart from each other in the second direction D2. The fence insulation pattern 214 may overlap the first gate structure 128, and may contact the first gate mask of the first gate structure 128.

The first sacrificial pattern 212 between the fence insulation patterns 214 may be removed to form a fourth opening defined by the spacer structure 208 on the second sidewall of the bit line structure 200 and the fence insulation pattern 214. The upper surface of the first active pattern 102 may be exposed by a bottom of the fourth opening.

A first contact plug layer filling the fourth opening may be formed to have a sufficient height, and an upper portion of the first contact plug layer may be removed to form a first contact plug 220 filling a lower portion of the fourth opening.

The first contact plug 220 may include, e.g., polysilicon doped with impurities. The first contact plug 220 may be electrically connected to the first active pattern 102.

The right cross-sectional views of FIGS. 24, 25, and 27 illustrate that the fourth conductive pattern 164a including tungsten may have a slightly reduced shape at the edge of the bit line structure 200 in the second direction D2.

In contrast, when the fourth conductive pattern 164a including tungsten cut between an upper portion and a lower portion thereof at the edge of the bit line structure 200 in the second direction D2 is formed, the spacer structure 208 may not be formed normally. Accordingly, the spacer structure 208 may not be insulated between the bit line structure 200 and the first contact plug layer, so that the first contact plug layer may fill a cut portion of the fourth conductive pattern. In this case, the bit line structure 200 and the first contact plug layer may be electrically connected to each other. Therefore, a short failure in which the bit line structure 200 and the first contact plug 220 are electrically connected to each other may occur. However, according to various example embodiments, the first spacer including the silicon oxide may not be formed on the first sidewall of the lower bit line structure 201, so that the fourth conductive pattern 164a in the bit line structure 200 may be formed to have a sufficient width in the first direction without being cut. Accordingly, the short failure in which the bit line structure 200 and the first contact plug 220 are electrically connected to each other may be decreased.

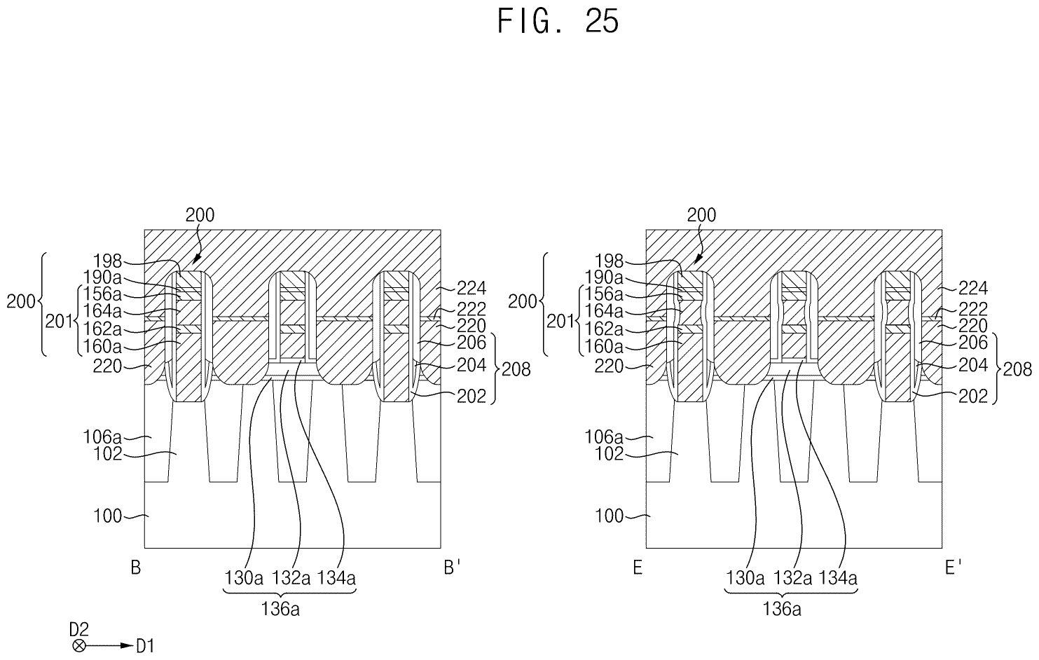

Referring to FIG. 25, an ohmic contact pattern 222 may be formed on an upper surface of the first contact plug 220. The ohmic contact pattern 222 may include, e.g., metal silicide, such as one or more of cobalt silicide, nickel silicide, titanium silicide, etc.

A first metal layer 224 may be formed on the ohmic contact pattern 222, the bit line structure 200, and the spacer structure 208 to fill the fourth opening. The first metal layer 224 may include, e.g., tungsten.

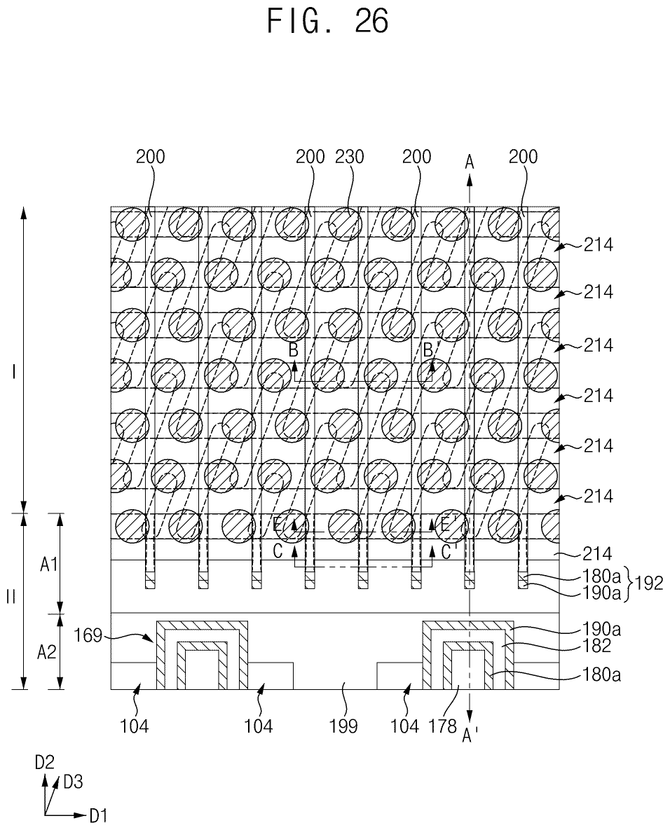

Referring to FIGS. 26 to 28, the first metal layer 224 may be patterned to form a landing pad pattern 230 on the ohmic contact pattern 222. In the patterning process for forming the landing pad pattern 230, an upper wiring (not shown) connected to the fourth conductive pattern 164a in the bit line structure 200 may be formed together.

In the patterning process of the first metal layer 224 on the first region I, a portion of the second capping pattern 156 in the bit line structure 200 and the spacer structure 208 on the bit line structure 200 may be etched together. Additionally, a fifth opening may be formed between the landing pad patterns 230.

In some example embodiments, a plurality of landing pad patterns 230 may be spaced apart from each other in each of the first and second directions D1 and D2 on the first region I. In a plan view, the plurality of landing pad patterns may be arranged to have a honeycomb shape or grid shape such as but not limited to a regular, rectangle or square grid shape. In the plan view, each of landing pad patterns 230 may have a circular shape, an oval shape, or a polygonal shape.

An upper insulation pattern 234 may be formed to fill the fifth opening. The upper insulation pattern 234 may be formed on the second capping pattern 198 and the second capping layer 199.

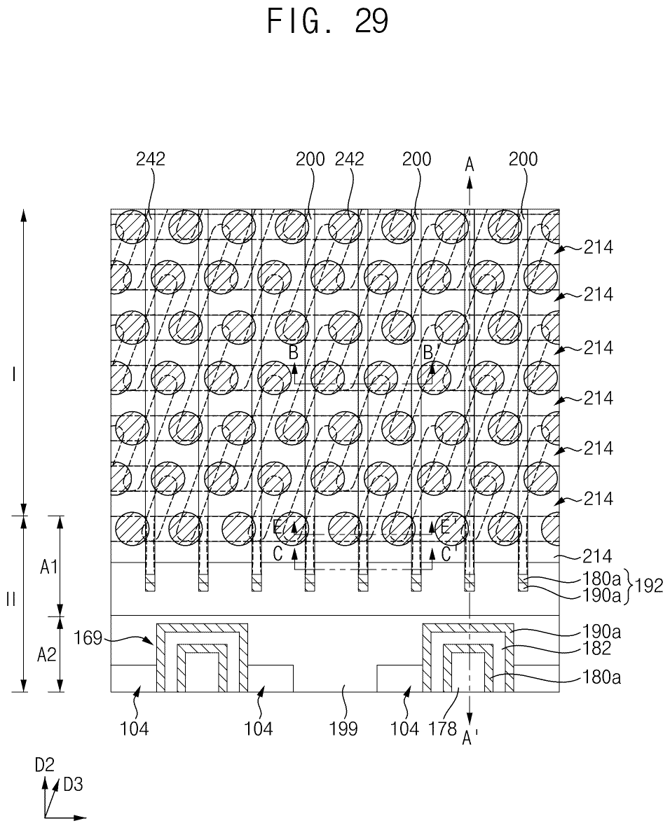

Referring to FIGS. 29 to 31, an etch stop layer 240 may be formed on the landing pad patterns 230 and the upper insulation pattern 234. Memory structures, such as but not limited to one or more of memristors or capacitors 248, may be formed through the etch stop layer 240, and the capacitors 248 may contact the landing pad patterns 230, respectively. Each of capacitors 248 may include a lower electrode 242, a dielectric layer 244, and an upper electrode 246; example embodiments are not limited thereto.

As described above, the first spacer including the silicon oxide may not be formed on the first sidewall of the bit line structure 200. The first offset spacer 180a and the insulation liner 190a including the silicon nitride may be stacked on the first sidewall of the lower bit line structure 201. Accordingly, defects due to the silicon oxide disposed on the first sidewall of the bit line structure 200 may be decreased in likelihood of occurrence and/or in impact from occurrence.

The semiconductor device may have the following structural characteristics. Below, structural features of the semiconductor device may be described.

Referring to FIGS. 29 to 31 again, the semiconductor device may include a substrate 100 including a first region I and a second region II. A first active pattern 102 and a first device isolation pattern 106a may be disposed on the first region I of the substrate 100. The second region II of the substrate 100 may include a dummy cell region A1 and a core/peripheral region A2. A second device isolation pattern 106b may be disposed on the dummy cell region A1 of the substrate 100. A second active pattern 104 and a second device isolation pattern 106b may be disposed in the core/peripheral region A2.

A first recess 110 extending in the first direction D1 may be through upper portions of the first active pattern 102 and the first device isolation pattern 106 on the first region I. A first gate structure 128 may be disposed in the first recess 110. The first gate structure 128 may include a first gate insulation layer 122, first gate electrodes 124a and 124b, and a first gate mask 126.

Insulation layer structures 136a may cover the first gate structure 128, the first device isolation pattern 106a, and a portion of the first active pattern 102 on the first region I. A first opening 142 may be formed between the insulation layer structures 136a. At least a central portion of the first active pattern 102 in the third direction D3 may be exposed by the bottom of the first opening 142.

In some example embodiments, the insulation layer structure 136a may have a structure in which a fourth insulation pattern 130a, a fifth insulation pattern 132a, and a sixth insulation pattern 134a are stacked. The fourth insulation pattern 130a and the sixth insulation pattern 134a may include, e.g., silicon oxide, and the fifth insulation pattern 132a may include, e.g., silicon nitride.

An impurity region may be disposed on an upper portion of the first active pattern 102 exposed by the first opening 142. For example, the impurity region may be doped with, e.g., implanted with, N-type impurities such as but not limited to one or more of arsenic or phosphorus.

A bit line structure 200 may be disposed in the first opening 142 and on the insulation layer structures 136a. The bit line structure 200 may include a lower bit line structure 201, an insulation liner 190a, and a second capping pattern 198 stacked.

The lower bit line structure 201 may have a stacked structure in which a third conductive pattern 160a, a first barrier pattern 162a, a fourth conductive pattern 164a, and a first capping pattern 156a are stacked. The lower bit line structure 201 may include a metal including at least tungsten.

The third conductive pattern 160a may include, e.g., polysilicon. The first barrier pattern 162a may include, e.g., metal silicon nitride, such as titanium silicon nitride (TiSiN). The fourth conductive pattern 164a may include, e.g., tungsten.

The lower bit line structure 201 may extend in the second direction D2. A plurality of the lower bit line structure 201 may be spaced apart from each other in the first direction D1. The lower bit line structure 201 may extend from the first region I to the dummy cell region A1, and an end of the lower bit line structure 201 in the second direction D2 may be positioned on the dummy cell region A1.

A second gate structure 178 may be disposed on the second active pattern 104 and the second device isolation pattern 106b on the core/peripheral region A2 in the second region II. The second gate structure 178 may include a second gate insulation layer 140, a fifth conductive pattern 170, a second barrier pattern 172, a sixth conductive pattern 174, and a first capping pattern 156a stacked.

The second gate insulation layer 140 may include silicon oxide. A stacked structure including the fifth conductive pattern 170, the second barrier pattern 172, the sixth conductive pattern 174, and the first capping pattern 156a may be formed by the same process as a process for forming the lower bit line structure 201. Therefore, the stacked structure including the fifth conductive pattern 170, the second barrier pattern 172, the sixth conductive pattern 174, and the first capping pattern 156a may be the same as the stacked structure of the lower bit line structure 201. The third conductive pattern 160a may include a material the same as a material of the fifth conductive pattern 170. The first barrier pattern 162a may include a material the same as a material of the second barrier pattern 172. The fourth conductive pattern 164a may include a material the same as a material of the sixth conductive pattern 174.

A second opening 169 exposing the second device isolation pattern 106b may be disposed between the lower bit line structure 201 and the second gate structure 178. A second recess 186 may be formed on a bottom of the second opening 169 adjacent to the first sidewall of the lower bit line structure 201. A bottom of the second recess 186 may be lower than the bottom of the second opening 169.

A first offset spacer 180a and an insulation liner 190a may cover the first sidewall of the end of the lower bit line structure 201 in the second direction D2. The first offset spacer 180a and the insulation liner 190a may directly contact to each other. The first offset spacer 180a may also cover the first sidewall of the insulation layer structure 136a below the lower bit line structure 201.

Additionally, a second offset spacer 180b may be disposed on a sidewall of the second gate structure 178. A first spacer 182 including silicon oxide may be disposed on the second offset spacer 180b on the sidewall of the second gate structure 178.

The first and second offset spacers 180a and 180b may include the same insulation material, and may not include the silicon oxide. The first and second offset spacers 180a and 180b may include, e.g., the silicon nitride.

In some example embodiments, a thickness of the first spacer 182 in a lateral direction may be greater than a thickness of the second offset spacer 180b in the lateral direction. The first spacer 182 may not be formed on the first offset spacer 180a on the first sidewall of the lower bit line structure 201. That is, a silicon oxide layer may not be formed on the first offset spacer 180a.

The insulation liner 190a may be conformally formed on an upper surface of the lower bit line structure 201 and the first offset spacer 180a on the first region I and the second region II, and the second recess 186, the second opening 169, a surface of the first spacer 182, and an upper surface of the second gate structure 178 on the second region II. That is, the insulation liner 190a may be continuously formed on the first and second regions I and II. The insulation liner 190a may include, e.g., the silicon nitride. The insulation liner 190a may not include the silicon oxide.

The first offset spacer 180a and the insulation liner 190a may be stacked on the first sidewall of the lower bit line structure 201. The first offset spacer 180a and the insulation liner 190a may include the same material, e.g., the silicon nitride, and thus the first offset spacer 180a and the insulation liner 190a formed on the first sidewall of the lower bit line structure 201 may be treated as a single silicon nitride layer. The first offset spacer may not be formed on the second device isolation pattern 106b exposed by bottoms of the second recess 186 and the second opening 169, and only the insulation liner 190a may be formed on the second device isolation pattern 106b exposed by the bottoms of the second recess 186 and the second opening 169. Therefore, a thickness of the silicon nitride layer formed on the first sidewall of the lower bit line structure 201 may be greater than a thickness of the silicon nitride layer formed on the second device isolation pattern 106b exposed by the bottoms of the second recess 186 and the second opening 169.

The second offset spacer 180b, the first spacer 182, and the insulation liner 190a may be sequentially stacked on the sidewall of the second gate structure 178.

As such, the first spacer 182 including the silicon oxide may be disposed on the sidewall of the second gate structure 178, and the first spacer 182 including the silicon oxide may not be disposed on the first sidewall of the lower bit line structure 201.

A seventh insulation pattern 196 may be disposed on the insulation liner 190a inside the second opening 169 and the second recess 186 to fill the second opening 169. The seventh insulation pattern 196 may include, e.g., the silicon oxide. The insulation liner 190a may be disposed on upper surfaces of the lower bit line structure 201 and the second gate structure 178 adjacent to the seventh insulation pattern 196.

A second capping pattern 198 may be disposed on the lower bit line structure 201 and the seventh insulation pattern 196 adjacent to the lower bit line structure 201. A second capping layer 199 may be disposed on the insulation liner 190a and the seventh insulation pattern 196 on the core/peripheral region A2 to cover an entire of the insulation liner 190a and the seventh insulation pattern 196 on the core/peripheral region A2.

The stacked structure of the lower bit line structure 201, the insulation liner 190a and the second capping pattern 198 on the first region I and the dummy cell region A1 may be referred to as a bit line structure 200.

The fourth conductive pattern 164a included in the lower bit line structure 201 on the first region I may have a first line width in the first direction. The first line width in the first direction may be the same depending on positions of the fourth conductive pattern 164a. The fourth conductive patterns 164a included in the lower bit line structure 201 on the dummy cell region A1 may have the same line width or different line widths depending on positions of the fourth conductive patterns 164a. The first line width may be substantially the same as a line width of the second capping pattern 198.

The fourth conductive pattern 164a included in the lower bit line structure 201 on the dummy cell region A1 may have a line width equal to or less than the first line width. That is, the fourth conductive pattern 164a adjacent to an end of the bit line structure 200 in the second direction D2 may have a line width equal to or less than the first line width. However, the fourth conductive pattern 164a may not be cut between an upper portion and a lower portion thereof. The fourth conductive pattern 164a may not be separated into the upper portion and the lower portion thereof.

Both sidewalls (e.g., second side walls) of the fourth conductive pattern 164a in the first direction D1 may have a shape that is further etched inward from a side wall of the second capping pattern 198 formed thereon. In some example embodiments, the fourth conductive pattern 164a may have a shape with a narrower line width in a middle portion in the vertical direction. In some example embodiments, the second sidewall of the fourth conductive pattern 164a may have a curvature.

As the fourth conductive pattern 164a adjacent to the end of the bit line structure 200 in the second direction D2 may not be cut between the upper portion and the lower portion thereof, so the defect due to cutting of the fourth conductive pattern 164a may be decreased.

A spacer structure 208 may be disposed on the second sidewall of the bit line structure 200. The spacer structure 208 may have a structure in which a plurality of spacers may be stacked. In some example embodiments, the spacer structure 208 may include a second spacer 202, a lower spacer 204, and a third spacer 206.

A fence insulation pattern 214 may be formed on a space between the spacer structures 208 in the first region I, and the fence insulation pattern 214 may be on a region that overlaps the first gate structure 128. The fence insulation pattern 214 may contact the first capping pattern 156a of the first gate structure 128. Additionally, a space defined by the spacer structure 208 and the fence insulation pattern 214 may be a fourth opening. The upper surface of the first active pattern 102 may be exposed to a bottom of the fourth opening.

A first contact plug 220 may be disposed in a lower portion of the fourth opening. The first contact plug 220 may include, e.g., polysilicon doped with impurities. A bottom of the first contact plug 220 may contact at least portion of the first active pattern 102, and thus the first contact plug 220 may be electrically connected to the first active pattern 102.

If the fourth conductive pattern 164a included in the bit line structure 200 on the dummy cell region A1 is cut the upper portion and the lower portion thereof, the first contact plug 220 may further fill a cutting portion of the fourth conductive pattern 164a. Therefore, the fourth conductive pattern 164a and the first contact plug 220 may be electrically connected to each other, so that an electrical short between fourth conductive pattern 164a and the first contact plug 220 may occur. However, as described above, the fourth conductive pattern 164a included in the bit line structure 200 on the dummy cell region A1 may not be cut between the upper portion and the lower portion thereof, and may have a sufficient line width in the first direction D1. Therefore, the electrical short between the fourth conductive pattern 164a and the first contact plug 220 may be decreased, e.g., decreased in likelihood of occurrence.

An ohmic contact pattern 222 may be disposed on an upper surface of the first contact plug 220. A landing pad pattern 230 may be disposed on the ohmic contact pattern 222. The ohmic contact pattern 222 may include, e.g., metal silicide such as cobalt silicide, nickel silicide, titanium silicide, etc. The landing pad pattern 230 may include, e.g., tungsten.

An upper surface of the landing pad pattern 230 may be higher than an upper surface of the bit line structure 200. A plurality of landing pad patterns 230 may be spaced apart from each other in each of the first and second directions D1 and D2 on the first region I. In a plan view, the plurality of the landing pad patterns 230 may be arranged to have a honeycomb shape or a grid shape. In the plan view, each of the landing pad patterns 230 may have a circular shape, an oval shape, or a polygonal shape.

A fifth opening may be disposed between the landing pad patterns 230. An upper portion of the bit line structure 200 exposed by the bottom of the fifth opening may have a third recess formed by an etching process. An upper insulation pattern 234 may be formed in the fifth opening. The upper insulation pattern 234 may include, e.g., the silicon oxide.

The landing pad pattern 230 may be formed only on a region between the bit line structures 200, and thus the landing pad pattern 230 may be formed only on the first region I and the dummy cell region A1. Accordingly, the upper insulation pattern 234 may be disposed on the second capping layer 199 on the core/peripheral region A2.

Upper surfaces of the landing pad pattern 230 and the upper insulation pattern 234 may be substantially coplanar with each other.

An etch stop layer 240 may be disposed on the landing pad patterns 230 and the upper insulation pattern 234. Memory structures such as memristors and/or capacitors 248 may pass through the etch stop layer 240, and the capacitors 248 may contact the landing pad patterns 230, respectively. Each of capacitors 248 may include a lower electrode 242, a dielectric layer 244, and an upper electrode 246.

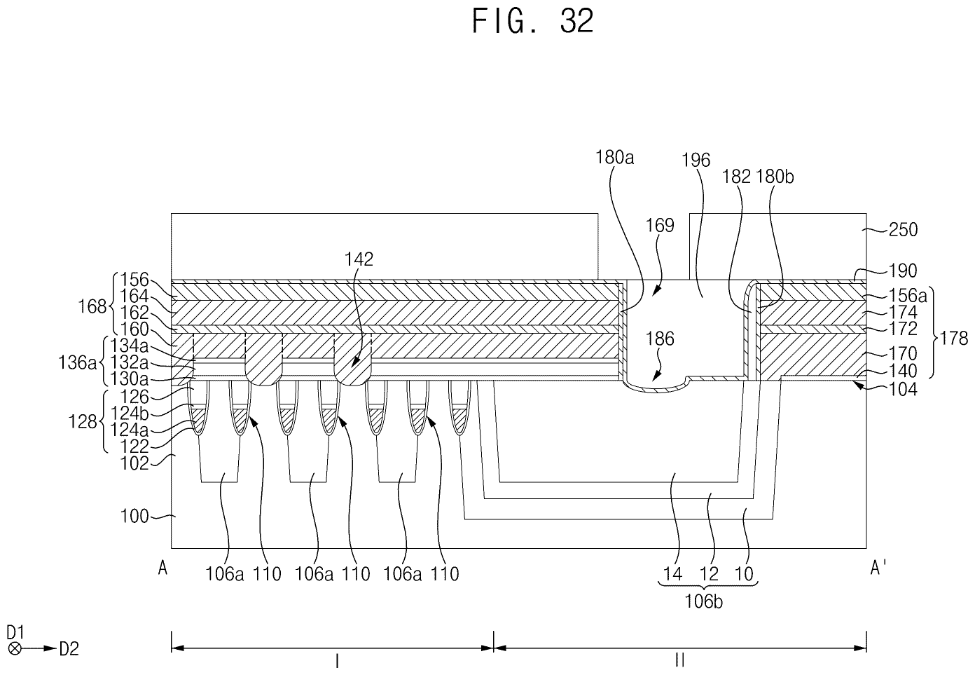

FIGS. 32 to 35 are cross-sectional views illustrating a method for manufacturing a semiconductor device according to some example embodiments.

FIGS. 32 to 35 are cross-sectional views taken along line A-A′ in the plan view. The method for manufacturing the semiconductor device described below may include substantially the same processes as those described with reference to FIGS. 1 to 31.

Referring to FIG. 32, first, the same processes as described with reference to FIGS. 1 to 16 may be performed to form a structure as shown in FIG. 16.

Thereafter, a second photoresist pattern 250 may be formed on the insulation liner layer 190 and the seventh insulation pattern 196. The second photoresist pattern 250 may expose the insulation liner layer 190 on a sidewall of the preliminary bit line structure 168 and the seventh insulation pattern 196 adjacent thereto. The second photoresist pattern 250 may cover an upper surface of the preliminary bit line structure 168 on the first region I, and the second gate structure 178, the second offset spacer 180b, the first spacer 182, the second active pattern 104, and a portion of the seventh insulation pattern 196 adjacent to the second gate structure 178 on the core/peripheral region A2.

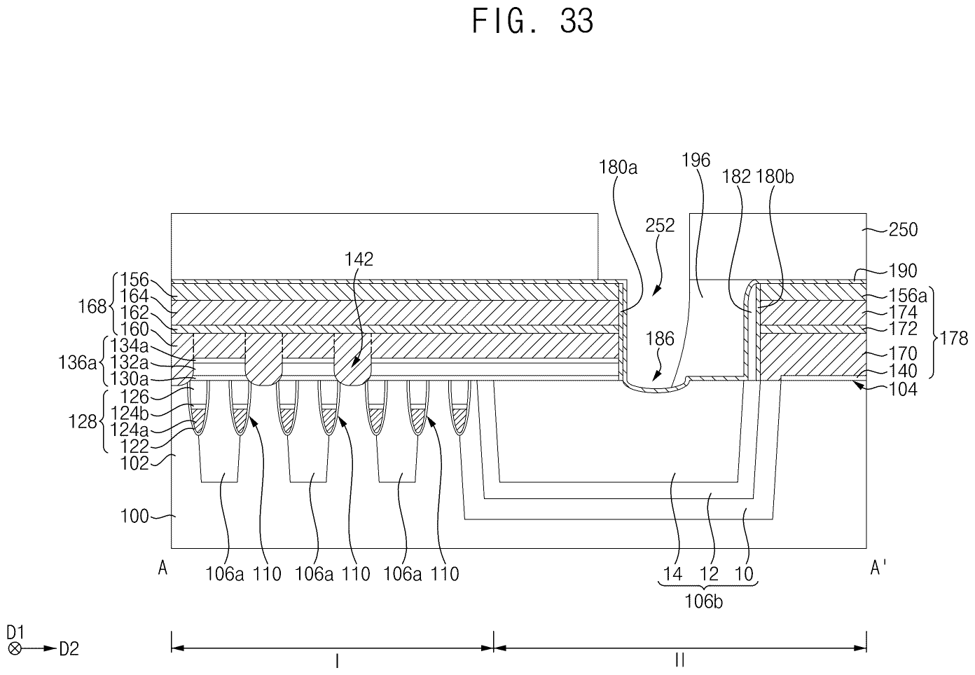

Referring to FIG. 33, the seventh insulation pattern 196 exposed by the second photoresist pattern 250 may be selectively removed to form an opening 252.

The removing process of a portion of the seventh insulation pattern 196 may include a wet etching process. The removing process may be a selective etching process of the silicon oxide. In the removing process of the portion of the seventh insulation pattern 196, an etchant may use, e.g., a hydrofluoric acid solution containing ammonium fluoride. In the removing process of the seventh insulation pattern 196, at least the insulation liner layer 190 on the sidewall of the preliminary bit line structure 168 may be exposed. That is, the insulation liner layer 190 may be exposed by one sidewall of the opening 252. Accordingly, the silicon oxide may not be formed on the insulation liner layer 190 on the sidewall of the preliminary bit line structure 168.

In some example embodiments, the insulation liner layer 190 may be exposed by the bottom of the opening 252.

The second photoresist pattern 250 may be removed.

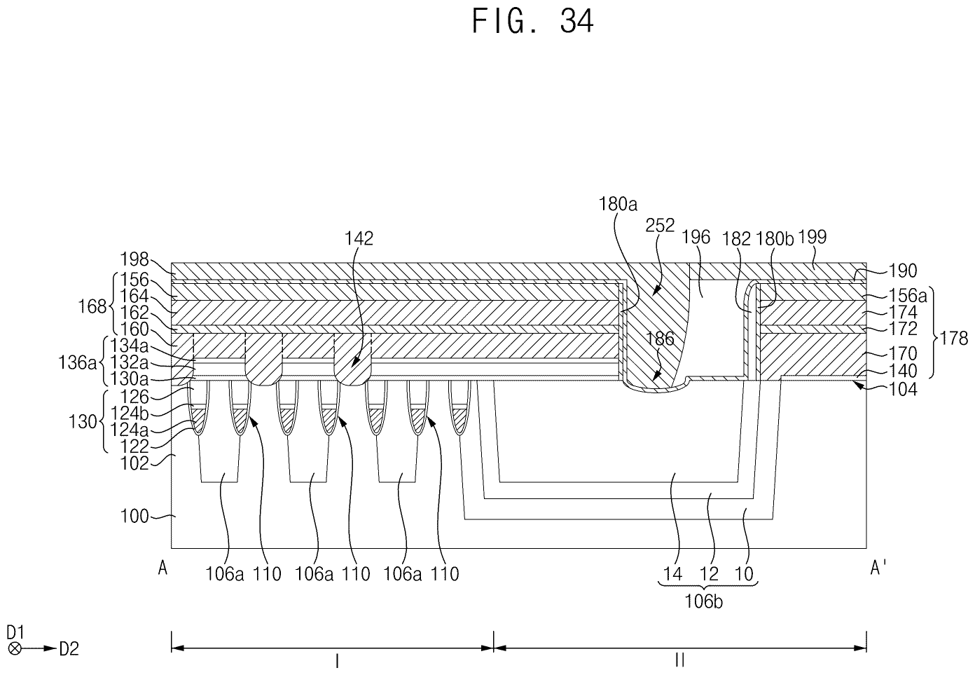

Referring to FIG. 34, a second capping layer 199 may be formed to cover the insulation liner layer 190 and the seventh insulation pattern 196, and may fill the opening 252. The second capping layer 199 may include, e.g., the silicon nitride.

The second capping layer 199 formed on the first region I and the dummy cell region A1 may be patterned to form a second capping pattern 198a. The second capping pattern 198a and the seventh insulation pattern 196 may be formed in the second opening 169 between the preliminary bit line structure 168 and the second gate structure 178.

The first offset spacer 180a, the insulation liner layer 190, and the second capping pattern 198a may be sequentially stacked on the sidewall of the preliminary bit line structure 168. The second capping pattern 198a including the silicon nitride may be formed on the sidewall of the preliminary bit line structure 168, so that a distance between an end of the preliminary bit line structure 168 in the second direction D2 and the seventh insulation patterns 196 may be increased.

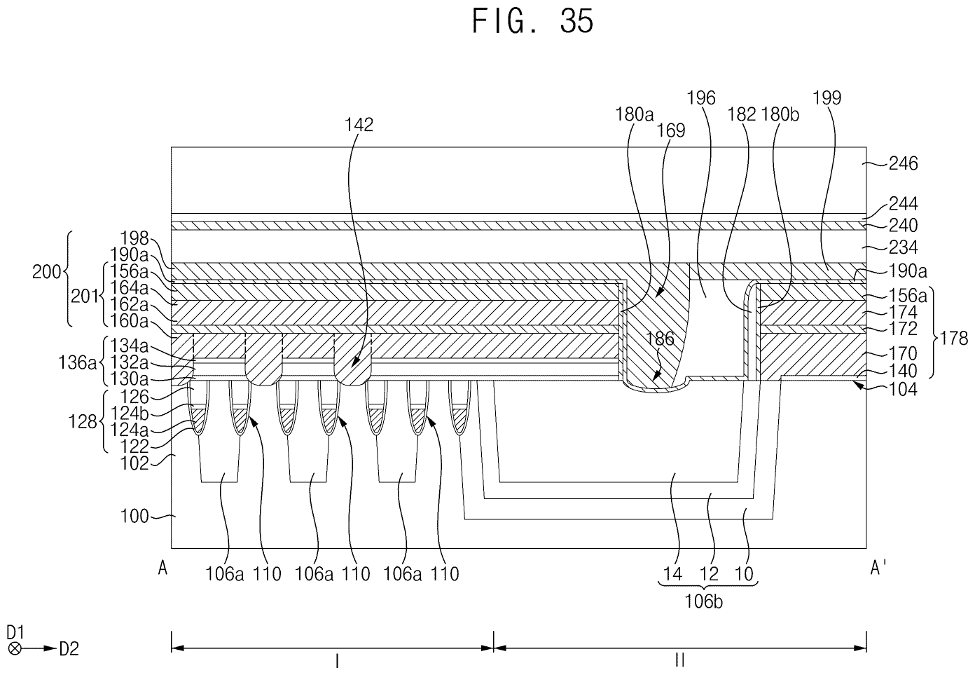

Thereafter, the same processes as described with reference to FIGS. 17 to 31 may be performed to manufacture the semiconductor device shown in FIG. 35.

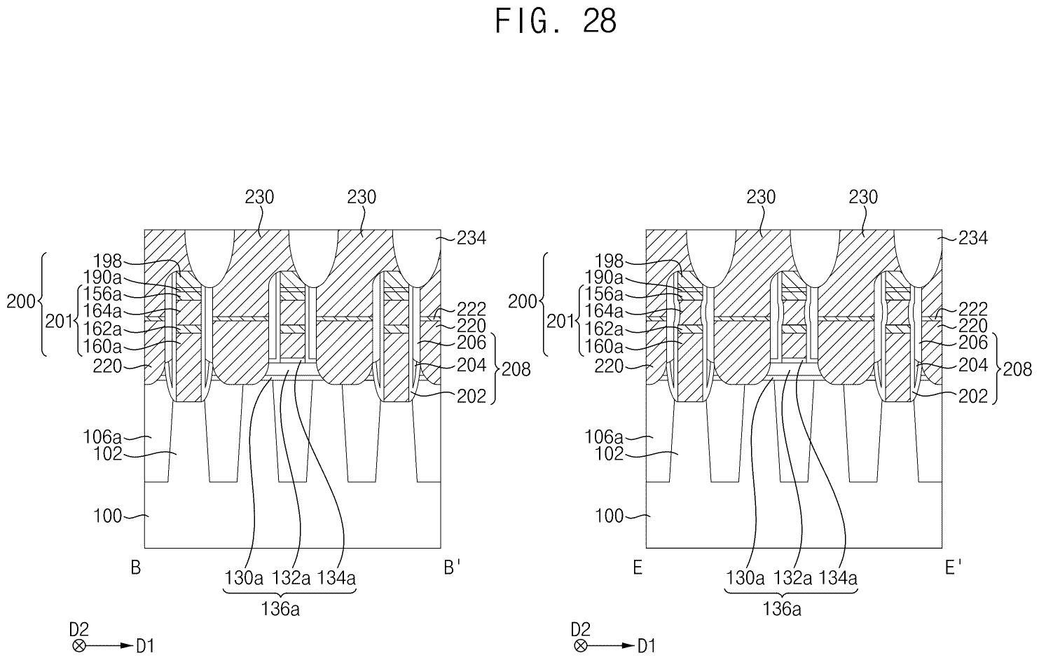

The semiconductor device may have the following structural characteristics. The semiconductor device may be the same as the semiconductor device described with reference to FIGS. 28 to 30, except for a stacked structure of the layers on the end of the lower bit line structure 201 in the second direction D2. Therefore, repeated explanations are omitted.

Referring to FIG. 35, the lower bit line structure 201 may extend from the first region I to the dummy cell region Al. An end of the lower bit line structure 201 in the second direction D2 may be disposed on the dummy cell region A1.

The first offset spacer 180a may be disposed on the first sidewall of the lower bit line structure 201.

The second gate structure 178 may be formed on the second active pattern 104 and the second device isolation pattern 106b in the second region II.

The second opening 169 exposing the second device isolation pattern 106b may be disposed between the lower bit line structure 201 and the second gate structure 178. The second recess 186 may be formed on a bottom of the second opening 169 adjacent to the end of the lower bit line structure 201 in the second direction D2. That is, a bottom of the second recess 186 may be lower than the bottom of the second opening 169.

The first offset spacer 180a may be disposed on the first sidewall of the lower bit line structure 201. Additionally, the second offset spacer 180b may be disposed on the sidewall of the second gate structure 178. The first and second offset spacers 180a and 180b may include, e.g., the silicon nitride.

The first spacer 182 including the silicon oxide may be disposed on the second offset spacer 180b of the sidewall of the second gate structure 178. In various example embodiments, a thickness of the first spacer 182 in the lateral direction may be greater than a thickness of the second offset spacer 180b in the lateral direction. The first spacer may not be formed on the first offset spacer 180a of the first sidewall of the lower bit line structure 201. That is, a silicon oxide layer may not be formed on the first offset spacer 180a.

The insulation liner 190a may be conformally formed on an upper surface of the lower bit line structure 201 and a surface of the first offset spacer 180a on the first region I and the second region II, and surfaces the second recess 186, the second opening 169 and the first spacer and an upper surface of the second gate structure 176 on the second region II. The insulation liner 190a may be continuously formed on the first and second regions I and II. The insulation liner 190a may include, e.g., silicon nitride.

A seventh insulation pattern 196 may be disposed on the insulation liner 190a in the second opening 169, and the seventh insulation pattern 196 may be laterally spaced apart from the insulation liner 190a on the first sidewall of the lower bit line structure 201. That is, an opening may be formed between the insulation liner 190a on the first sidewall of the lower bit line structure 201 and the seventh insulation pattern 196. In various example embodiments, the insulation liner 190a on the first sidewall of the lower bit line structure 201 and the insulation liner 190a on the second device isolation pattern 106b adjacent to the first sidewall of the lower bit line structure 201 may be exposed by the opening.

A second capping pattern 198a may be disposed on the insulation liner 190a on the upper surface of the lower bit line structure 201 and on the seventh insulation pattern 196 in the first region I and the dummy cell region A1, and may fill the opening. The second capping pattern 198a inside the opening may contact a sidewall of the seventh insulation pattern 196.

The second capping pattern 198a may include, e.g., silicon nitride. The first offset spacer 180a, the insulation liner 190a, and the second capping pattern 198 may be stacked on the first sidewall of the lower bit line structure 201. The first offset spacer 180a, the insulation liner 190a, and the second capping pattern 198 may include the same material, e.g., the silicon nitride, and thus the first offset spacer 180a, the insulation liner 190a, and the second capping pattern 198 formed on the first sidewall of the lower bit line structure 201 may be treated as one nitride layer. Accordingly, the silicon nitride layer may be disposed adjacent to the first sidewall of the lower bit line structure 201, and a silicon oxide layer may not be disposed adjacent to the first sidewall of the lower bit line structure 201.

A thickness of the nitride layer formed on the first sidewall of the lower bit line structure 201 may be greater than a thickness of the nitride layer (i.e., the insulation liner) on the second device isolation pattern 106b.

The second offset spacer 180b, the first spacer 182, and the insulation liner 190a may be stacked on the sidewall of the second gate structure 178. The sidewall of the second gate structure 178 may not contact the second capping pattern 198.

As such, the first spacer 182 including the silicon oxide may be disposed on the sidewall of the second gate structure 178, and the first spacer 182 including the silicon oxide may not be disposed on the first sidewall of the lower bit line structure 201.

The second capping layer 199 may be disposed on the second gate structure 178 and the seventh insulation pattern 196 on the core/peripheral region A2, and the second capping layer 199 may cover the second gate structure 178 and the seventh insulation pattern 196 on the core/peripheral region A2.

A stacked structure including the lower bit line structure 201, the insulation liner 190a and the second capping pattern 198 formed on the first region I and the dummy cell region Al is referred to as the bit line structure 200.

The fourth conductive pattern 164a in the lower bit line structure 201 formed on the first region I may have a first line width in the first direction. In the first region I, the first line width in the first direction may be the same depending on positions of the fourth conductive pattern 164a. The fourth conductive patterns 164a included in the lower bit line structure 201 on the dummy cell region A1 may have the same line width or different line widths depending on positions thereof. The first line width may be substantially the same as a width of the second capping pattern 198.

The fourth conductive pattern 164a included in the lower bit line structure 201 on the dummy cell region A1 may have a line width equal to or slightly less than the first line width. The fourth conductive pattern 164a may not be cut between an upper portion and a lower portion thereof. The fourth conductive pattern 164a may not be separated into the upper portion and the lower portion thereof.

The second sidewall of the fourth conductive pattern 164a may have a shape that is further etched inward from a sidewall of the second capping pattern 198 formed thereon. In some example embodiments, the fourth conductive pattern 164a may have a shape with a narrower line width in a middle portion in the vertical direction. In some example embodiments, the second sidewall of the fourth conductive pattern 164a may have a curvature, such as a concave curvature, a convex curvature, or a concave-convex curvature.

In the semiconductor device, the fourth conductive pattern 164a including tungsten included in the bit line structure may not be cut between the upper portion and the lower portion thereof at a region adjacent to the end of the bit line structure 200 in the second direction. Accordingly, defects caused by cutting the fourth conductive pattern included in the bit line structure may be decreased in likelihood of occurrence and/or in impact from occurrence.

The foregoing is illustrative of various example embodiments and is not to be construed as limiting thereof. Although a few example embodiments have been described, those skilled in the art will readily appreciate that many modifications are possible in the example embodiments without materially departing from the novel teachings and advantages of the present inventive concept. Additionally example embodiments are not necessarily mutually exclusive with one another. For example, some example embodiments may include one or more features described with reference to one or more drawings, and may also include one or more other features described with reference to one or more other drawings.

What is claimed is:

1. A semiconductor device, comprising:
a substrate including a first region and a second region;
first gate structures extending in a first direction, each of the first gate structures in a first recess defined at the first region of the substrate;
lower bit line structures on the substrate, the lower bit line structures arranged from the first region to the second region adjacent to the first region, the lower bit line structures extending in a second direction perpendicular to the first direction;
a second gate structure on the second region of the substrate, the second gate structure spaced apart from the lower bit line structure;
a first offset spacer on a first sidewall corresponding to an end of each of the lower bit line structures in the second direction;
a second offset spacer and a first spacer sequentially arranged on a sidewall of the second gate structure;
an insulation liner layer conformally on each of upper surfaces of the lower bit line structures, a surface of the first offset spacer, the substrate between the lower bit line structure and the second gate structure, and upper surfaces of the first spacer and the second gate structure; and
a capping pattern covering the lower bit line structures and an upper portion of the second gate structure,
wherein the first offset spacer and the insulation liner layer include silicon nitride.

2. The semiconductor device of claim 1, wherein the first offset spacer and the insulation liner layer directly contact each other.

3. The semiconductor device of claim 1, wherein the first spacer includes silicon oxide.

4. The semiconductor device of claim 1, wherein the second offset spacer includes a material the same as at least one material of the first offset spacer.

5. The semiconductor device of claim 1, wherein the lower bit line structure includes a metal including tungsten.

6. The semiconductor device of claim 1, wherein the lower bit line structure has a structure in which a first conductive pattern including polysilicon, a second conductive pattern including tungsten, and a first lower capping pattern including silicon nitride are stacked.

7. The semiconductor device of claim 6, wherein
the second gate structure has a structure in which a gate insulation layer, a third conductive pattern, a fourth conductive pattern, and a second lower capping pattern are stacked, and
the third conductive pattern includes a material the same as at least one material of the first conductive pattern, and the fourth conductive pattern includes a material the same as at least one material of the second conductive pattern, and the second lower capping pattern includes a material the same as the at least one material of the lower capping pattern.

8. The semiconductor device of claim 6, wherein the second conductive pattern on the first region has a first line width, and the second conductive pattern on the second region has a second line width less than or equal to the first line width.

9. The semiconductor device of claim 1, wherein the first region of the substrate includes a first active pattern and a first device isolation pattern, and the second region of the substrate includes a second active pattern and a second device isolation pattern.

10. The semiconductor device of claim 9, wherein the lower bit line structure disposed on the second region of the substrate is on the second device isolation pattern.

11. The semiconductor device of claim 9, wherein the first sidewall of the lower bit line structure is on the second device isolation pattern, and the second device isolation pattern is between the lower bit line structure and the second gate structure.

12. The semiconductor device of claim 11, wherein a second recess is defined on an upper surface of the second device isolation pattern adjacent to the lower bit line structure.

13. The semiconductor device of claim 1, further comprising:
an insulation pattern filling a space between the lower bit line structure and the second gate structure on the second region of the substrate.

14. The semiconductor device of claim 1, further comprising:
a first contact plug contacting the substrate and a landing pad pattern on the first contact plug, a stack including the contact plug and the landing pad pattern arranged between the lower bit line structures; and
a memory structure contacting on the landing pad pattern.

15. A semiconductor device, comprising:
a substrate including first and second regions;
a first active pattern and a first device isolation pattern on the first region of the substrate;
a second active pattern and a second device isolation pattern on the second region of the substrate;
first gate structures in first recesses of the substrate of the first region, the first gate structures extending in a first direction;
a lower bit line structure on the substrate extending in a second direction perpendicular to the first direction, the lower bit line structure arranged from the first region to the second region adjacent to the first region;
a second gate structure on the second region of the substrate, the second gate structure being spaced apart from the lower bit line structure;
a first offset spacer and a first insulation liner layer arranged on a first sidewall corresponding to an end of each of the lower bit line structures in the second direction; and
a second offset spacer, a first spacer, and a second insulation liner layer sequentially arranged on a sidewall of the second gate structure,
wherein the first offset spacer and the first insulation liner layer have no silicon oxide.

16. The semiconductor device of claim 15, wherein
the first and second offset spacers and the first and second insulation liner layers include silicon nitride, and the first spacer includes silicon oxide.

17. The semiconductor device of claim 15, wherein the lower bit line structure on the second region of the substrate is on the second device isolation pattern.

18. The semiconductor device of claim 15, wherein the lower bit line structure has a structure in which a first conductive pattern including polysilicon, a second conductive pattern including tungsten, and a lower capping pattern including silicon nitride are stacked.

19. A semiconductor device, comprising:
a substrate including first and second regions;
a first active pattern and a first device isolation pattern on the first region of the substrate;
a second active pattern and a second device isolation pattern on the second region of the substrate;
first gate structures in a first recess of the first region of the substrate, the first gate structures extending in a first direction;
lower bit line structures on the substrate, the lower bit line structures arranged from the first region to the second region adjacent to the first region, the lower bit line structures extending in a second direction perpendicular to the first direction, the lower bit line structures including at least tungsten;
a second gate structure on the second region of the substrate to be spaced apart from the lower bit line structures, the second gate structure including a conductive material the same as at least one material of the lower bit line structure;
a first offset spacer disposed on a first sidewall corresponding to an end of each of the lower bit line structures in the second direction;
a second offset spacer and a first spacer sequentially on a sidewall of the second gate structure; and
an insulation liner layer conformally on each of upper surfaces of the lower bit line structures, the surface of the first offset spacer, the second device isolation pattern between the lower bit line structure and the second gate structure, and upper surfaces of the first spacer and the second gate structure.

20. The semiconductor device of claim 19, wherein the first offset spacer and the insulation liner layer include silicon nitride.
